(19) United States
(12) Patent Application Publication
(10) Pub. No.: US 2009/0001881 A1
(43) Pub. Date: Jan. 1, 2009

(54) ORGANIC EL DISPLAY AND MANUFACTURING METHOD THEREOF

(76) Inventor: Masaya NAKAYAMA, Kanagawa (JP)

Correspondence Address: BIRCH STEWART KOLASCH & BIRCH, PO BOX 747, FALLS CHURCH, VA, 22040-0747, US

(21) Appl. No.: 12/146,254

(22) Filed: Jun. 25, 2008

(30) Foreign Application Priority Data
Jun. 28, 2007 (JP) 2007-170942
Apr. 30, 2008 (JP) 2008-119003

(51) Int. Cl. H01L 51/54

(52) U.S. Cl. 313/504

(57) ABSTRACT

The present invention provides an organic electroluminescence display having an organic electroluminescence element including, on a substrate, at least a lower electrode, an organic layer including at least a light-emitting layer, and an upper electrode in this order, and on the upper electrode, a thin film field effect transistor which includes at least a gate electrode, a gate insulating layer, an active layer, a source electrode and a drain electrode and drives the organic electroluminescence element, wherein the active layer includes an oxide semiconductor; and a manufacturing method thereof.

### CROSS-REFERENCE TO RELATED APPLICATION

This application claims priority under 35 USC 119 from Japanese Patent Application Nos. 2007-170942 and 2008-119003, the disclosures of which are incorporated by reference herein.

### BACKGROUND OF THE INVENTION

1. Field of the Invention

The present invention concerns an organic EL display in which a thin film field effect transistor for driving an organic EL element is disposed on the organic EL element, as well as a manufacturing method thereof. Particularly, it relates to an active-type organic EL display capable of obtaining a high aperture ratio, and having high definition, high brightness, high stability, high reliability and high durability, as well as a manufacturing method thereof.

2. Description of the Related Art

In recent years, flat panel displays (FPDs) have been put to practical use, due to the progress made in liquid crystal and electroluminescence (EL) technologies, etc. In particular, an organic electroluminescence element (hereinafter referred to as an “organic EL element” in some cases) formed using a thin film material which emits light by excitation due to application of electric current can provide light emission of high brightness at a low voltage, and thus is expected to achieve reduction in device thickness, weight, and size, and power saving, etc. in wide ranging applications including mobile phone displays, personal digital assistants (PDA), computer displays, car information displays, TV monitors, and general illumination.

These FPDs are driven by an active matrix circuit including field effect-type thin film transistors each using, as an active layer, an amorphous silicon thin film or a polycrystalline silicon thin film provided on a glass substrate. (In the description below, a field effect-type thin film transistor is sometimes referred to as a “thin film transistor” or “TFT”.)

On the other hand, for attaining even higher definition, higher brightness and higher durability in the active-type organic EL display, it has been known that a top-emission type is advantageous, due to being able to obtain a high aperture ratio. However, in the organic EL element having the top-emission structure, since it is difficult to form a transparent electric conductive layer such as ITO directly on an organic layer without any damage, it is difficult to provide a practically useful element having high efficiency and high durability at present.

As another approach, Japanese Patent Application Laid-Open (JP-A) No. 2005-242028, for example, discloses forming TFT superposed above an organic EL element having a bottom-emission structure, wherein the TFT is constituted with an organic semiconductor. As film formation with an organic TFT using an organic semiconductor can be conducted at low temperature, the organic TFT can be formed on an organic EL element with no damage to the organic EL element. However, the organic TFT has a problem in view of drive stability and also has a problem in view of reliability such that strict sealing is necessary against the external atmosphere and moisture in order to enhance the storage stability. Further, since the organic TFT has low carrier mobility, a size (channel width) of the TFT increases extremely in order to increase driving current. Therefore, it is difficult to provide an organic EL display having high definition and high brightness.

On the other hand, transistors using thin silicon films are favorable in view of stability and operational reliability, but as their manufacturing process requires a thermal treatment step at a relatively high temperature, it involves a problem in that damage is caused to an organic EL clement in a case of forming the transistor above the organic EL element.

TFTs using, as a semiconductor thin film, a film of an amorphous oxide, such as an In—Ga—Zn—O-based amorphous oxide, which can be formed at a low temperature, have been disclosed in JP-A No. 2006-165529 and IDW/AD'05, pages 845-846 (Dec. 6, 2005). As the films for a TFT made with an amorphous oxide semiconductor can be formed at room temperature, the TFT can be prepared on a film (flexible substrate). Therefore, amorphous oxide semiconductors have been attracting attention as a material for active layers of film (flexible) TFTs lately. For example, it has been reported that a TFT formed using a-IGZO has a field effect mobility of about 10 cm²/Vs even on a PEN substrate, which is higher than that of an a-Si TFT on glass, in NATURE, vol. 432, pages 488-492 (Nov. 25, 2004).

However, in the case of using, as for example, a drive circuit of a display, a TFT formed using a-IGZO, there are problems in that mobility ranges from 1 cm²/Vs to 10 cm²/Vs, which provides insufficient performance, the OFF current is high, and the ON-OFF ratio is low. Particularly, in order to apply such a TFT to a display incorporating organic EL elements, further increase in mobility and improvement in ON-OFF ratio are required.

### SUMMARY OF THE INVENTION

The present invention has been made in view of the above circumstances and provides an organic EL display and a manufacturing method of the organic EL display with the following aspects.

A first aspect of the invention provides an organic EL display comprising:

an organic EL element comprising on a substrate at least a lower electrode, an organic layer comprising at least a light-emitting layer, and an upper electrode, in this order; and

a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor.

A second aspect of the invention provides a method of manufacturing an organic EL display comprising:

an organic EL element comprising on a substrate at least a lower electrode, an organic layer comprising at least a light-emitting layer, and an upper electrode, in this order; and

a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor,

wherein the method comprises forming the organic EL element and forming the thin film field effect transistor successively on the substrate.

### BRIEF DESCRIPTION OF THE DRAWINGS

FIG. 1 is a schematic diagram showing the structure of an organic EL display according to the invention.

FIG. 2 is a schematic diagram showing the structure of an organic EL display according to another embodiment of the invention.

FIG. 3 is a schematic diagram showing the structure of an organic EL display according to still another embodiment of the invention.

FIG. 4 is a schematic diagram showing the structure of a TFT used in the display according to the invention.

FIG. 5 is a schematic diagram showing the structure of a TFT used in the display according to another embodiment of the invention.

FIG. 6 is a schematic diagram of a pixel-circuit of an organic EL display according to the invention.

### DETAILED DESCRIPTION OF THE INVENTION

It is an object of the invention to provide an organic EL display in which a TFT for driving an organic EL element is disposed on the organic EL element, as well as a manufacturing method thereof, and, in particular, to provide an active-type organic EL display capable of obtaining a high aperture ratio and having high definition, high brightness, high stability, high reliability and high durability, as well as a manufacturing method thereof.

The organic EL display of the present invention includes an organic EL element comprising on a substrate at least a lower electrode, an organic layer comprising at least a light-emitting layer, and an upper electrode, in this order, and a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor.

Preferably, a protective insulating layer is disposed between the upper electrode and the thin film field effect transistor, and the upper electrode and at least one of the source electrode or the drain electrode are electrically connected through a contact hole formed in the protective insulating layer.

Preferably, the lower electrode is a light transmitting electrode, and the upper electrode is a light reflective electrode.

Preferably, the lower electrode is an anode, and the upper electrode is a cathode.

Preferably, a polarity of the thin film field effect transistor is an N-type.

Preferably, the oxide semiconductor of the active layer is an amorphous oxide semiconductor

Preferably, an electric resistance layer containing an oxide semiconductor is disposed between the active layer and at least one of the source electrode or the drain electrode.

Preferably, the active layer is in contact with the gate insulating layer, and the electric resistance layer is in contact with at least one of the source electrode or the drain electrode.

Preferably, the electric resistance layer is thicker than the active layer.

Preferably, an electric conductivity changes continuously between the electric resistance layer and the active layer.

Preferably, an oxygen concentration of the active layer is lower than an oxygen concentration of the electric resistance layer.

Preferably, the oxide semiconductor of the active layer and the electric resistance layer is at least one material selected from the group consisting of In, Ga, and Zn, or a composite oxide thereof. More preferably, the oxide semiconductor contains In and Zn, and a composition ratio between Zn and In in the electric resistance layer (represented by a ratio of Zn to In, Zn/In) is larger than a composition ratio Zn/In in the active layer.

Preferably, the active layer has an electric conductivity of 10⁻⁴ Scm⁻¹ or more, and less than 10² Scm⁻¹, and more preferably 10⁻¹ Scm⁻¹ or more, and less than 10² Scm⁻¹.

Preferably, a ratio of an electric conductivity of the active layer to an electric conductivity of the electric resistance layer (electric conductivity of active layer/electric conductivity of electric resistance layer) is from 10¹ to 10¹⁰, and more preferably from 10² to 10⁸.

Preferably, the substrate is a flexible resin substrate.

The method of manufacturing an organic EL display of the present invention is a manufacturing method of an organic EL display, which includes an organic EL element comprising on a substrate at least a lower electrode, an organic layer comprising at least a light-emitting layer, and an upper electrode, in this order, and a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor, wherein the method comprises forming the organic EL element and forming the thin film field effect transistor successively on the substrate.

In a TFT using an oxide semiconductor, film formation can be conducted at room temperature, and therefore, the TFT can be formed on an organic EL element without damaging the organic EL element. As a TFT using the oxide semiconductor has higher mobility than an organic TFT, a current that can be applied to an organic EL element increases, whereby a display having high brightness can be provided, and in addition, it has superior characteristics with respect to drive stability and storage stability, such as not requiring a sealing film, as compared with the organic TFT. Particularly, by using an In—Ga—Zn—O-based oxide for an active layer, a TFT having a field effect mobility of 10 cm²/Vs and an ON/OFF ratio of more than 10³ can be obtained. Further, a TFT having both excellent OFF characteristics and high mobility can be provided by a constitution, wherein an oxide semiconductor layer includes at least an active layer and an electric resistance layer with an electric conductivity lower than that of the active layer, the active layer is in contact with a gate insulating layer, and the electric resistance layer is electrically connected between the active layer and at least one of the source electrode or the drain electrode. Particularly, a constitution having at least the electric resistance layer and the active layer in a layered form, wherein the active layer is in contact with the gate insulating layer, and the electric resistance layer is in contact with at least one of the source electrode or the drain electrode has been found to be an effective means.

The invention provides an active-type organic EL display in which a TFT for driving an organic EL element is disposed on the organic EL element, and which is capable of obtaining a high aperture ratio and has high definition, high brightness, high stability, high reliability and high durability, and also provides a manufacturing method thereof.

Next, a best mode for practicing the invention is to be described in detail.

### 1. Organic EL Display

The organic EL display of the invention includes, on a substrate, an organic EL element having at least a lower electrode, an organic layer containing at least a light-emitting layer and an upper electrode, in this order, and a TFT for driving the organic EL element having at least a gate electrode, a gate insulating layer, an active layer containing an oxide semiconductor, a source electrode, and a drain electrode on the upper electrode. Since the TFT is disposed at a back side of the organic EL element with respect to a light-extraction side of the organic EL element, an aperture for extracting light emission of the organic EL element can be made larger. Preferably, a protective insulating layer is disposed between the TFT and the organic EL element, and the upper electrode of the organic EL element and the source electrode or the drain electrode of the TFT are electrically connected by way of a contact hole formed in the protective insulating layer. Preferably, the lower electrode is a light transmitting electrode and the upper electrode is a light reflective electrode.

The organic EL display of the invention is to be described in detail with reference to the drawings.

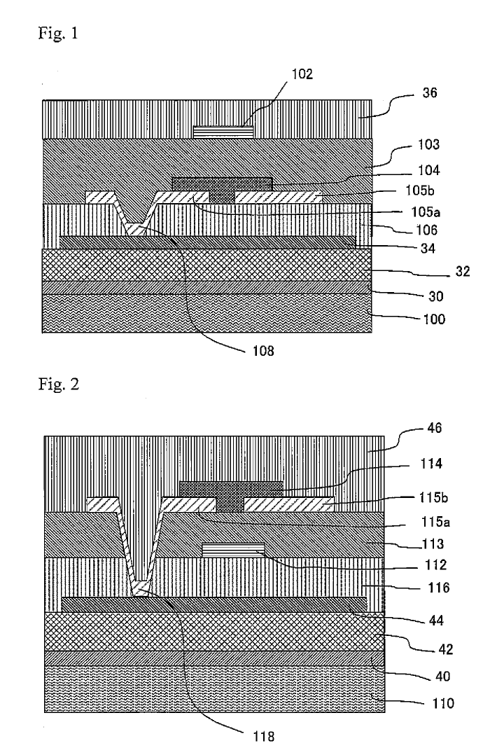

FIG. 1 is a conceptual sectional view showing a constitution of an example of an organic EL display according to the invention.

On a substrate 100, an organic EL element portion having a lower electrode 30, an organic layer 32 containing at least a light-emitting layer, and an upper electrode 34, a protective insulating layer 106, in this order; and a TFT portion having at least a source electrode 105a, a drain electrode 105b, an active layer 104, a gate insulating layer 103, and a gate electrode 102 are provided. The entire display is covered with an insulating film 36. One of the source electrode 105a or the drain electrode 105b and the upper electrode 34 are connected electrically through a contact hole 108 disposed in the protective insulating layer. In this constitution, the substrate and the lower electrode are transparent, the upper electrode is light reflective, and thereby the light generated upon light emission is extracted through the substrate to the outside.

FIG. 2 is a conceptual sectional view showing the constitution of an organic EL display of another embodiment according to the invention.

The structure of the TFT is different from that of FIG. 1, and it has a gate electrode 112, a gate insulating layer 113, a source electrode 115a, a drain electrode 115b, and an active layer 114 on a protective insulating layer 116. One of the source electrode 115a or the drain electrode 115b and the upper electrode 44 are electrically connected through a contact hole 118 formed passing through the protective insulating layer 116 and the gate insulating layer 113.

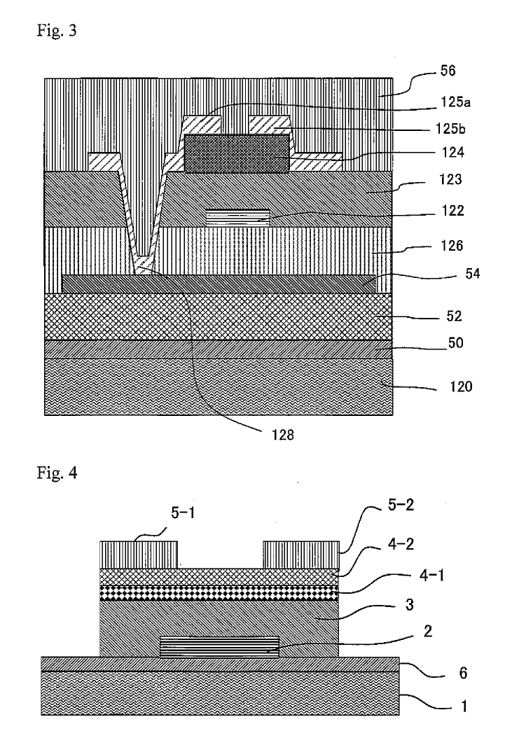

FIG. 3 is a conceptual sectional view showing the constitution of an organic EL display of still another embodiment according to the invention.

As is similar to FIG. 2, the structure of the TFT in FIG. 3 is different from that in FIG. 1, and it has a gate electrode 122, a gate insulating layer 123, an active layer 124, a source electrode 125a, and a drain electrode 125b on a protective insulating layer 126. One of the source electrode 125a or the drain electrode 125b and the upper electrode 54 are electrically connected through a contact hole 128 formed passing through the protective insulating layer 126 and the gate insulating layer 123.

In any of the structures, the TFT is disposed at a back surface of the organic EL element on a side opposite to a light-extraction side. Since the TFT used in the invention is excellent in the ON/OFF characteristic and capable of supplying a large electric current, it enables downsizing of TFT so as to also sufficiently applicable to a high compact arrangement of organic EL elements, and thereby an opening portion of the organic EL element can be disposed widely.

Accordingly, an organic EL display having high reliability, high definition, high brightness and high durability is provided.

### 2. TFT

The TFT used in the invention is an active-type element having at least a gate electrode, a gate insulating layer, an active layer, a source electrode, and a drain electrode in this order, and having a function of switching a current between the source electrode and the drain electrode by applying a voltage to the gate electrode and controlling the current flowing to the active layer. An oxide semiconductor is used for the active layer of the TFT in the invention. The oxide semiconductor layer can be formed at a low temperature, and thereby can be formed with less damage to the organic EL element. Further, compared with an organic semiconductor such as pentacene, it is excellent not only in mobility but also excellent in view of drive stability and storage stability. Particularly, an amorphous oxide semiconductor is preferred for the active layer of the TFT in view of the uniformity of TFT characteristics and stability of characteristics. With respect to the TFT structure, any of a stagger structure or a reversed stagger structure can be formed.

Preferably, the TFT has an N-type polarity.

An organic EL element usually has a structure having a transparent anode using ITO for a lower electrode and a light reflective cathode using Al for an upper electrode. A source electrode or a drain electrode of a driving TFT is preferably connected with the upper electrode, that is, the cathode of the organic EL element in view of manufacturing process or constitution thereof. For example, in a case of constituting a pixel circuit as a simple 2-transistor-1-capacitor (2Tr-1C), particularly excellent performance is obtained in driving characteristics by connecting the drain electrode of TFT with the cathode of the organic EL element, grounding the anode of the organic EL element and using a N-type TFT. This is because stable driving is possible since the gate voltage of the driving TFT is free from influences by driving voltage for the organic EL element. Accordingly, an existent compensation circuit such as 4Tr for stabilization is no more necessary, which enables downsizing of the TFT portion and facilitates the design for an organic EL display of higher definition, higher brightness, and higher durability.

Preferably, the active layer in the present invention contains an oxide semiconductor, and thereby can be formed at a low temperature. Preferably, the oxide semiconductor in the present invention is an amorphous oxide semiconductor.

Preferably, the TFT in the present invention includes at least an active layer and an electric resistance layer which has an electric conductivity lower than that of the active layer, and the active layer is closer to the gate insulating layer, and the electric resistance layer is disposed with electrical contact between the active layer and at least one of the source electrode or the drain electrode. Preferably, the electric resistance layer in the present invention also contains an oxide semiconductor. Hereinafter, it may refer as a “semiconductor layer” as a definition to mean a term including an active layer and an electric resistance layer.

More preferably, at least the active layer and the electric resistance layer are formed to be layered, and the active layer is in contact with the gate insulating layer, and the electric resistance layer is contact with at least one of the source electrode or the drain electrode.

Preferably, the electric resistance layer is thicker than the active layer in view of drive stability.

Further, as another embodiment, an embodiment in which the electric conductivity between the electric resistance layer and the active layer changes continuously is also preferable. In the structure, there is no distinct boundary between the electric resistance layer and the active layer. With respect to a total thickness of a semiconductor layer including the electric resistance layer and the active layer, a 10% region adjacent to the gate insulating layer is defined as an active layer, and a 10% region for the thickness of the semiconductor layer adjacent to the source electrode or the drain electrode is defined as an electric resistance layer.

An oxygen concentration of the active layer is preferably lower than an oxygen concentration of the electric resistance layer.

The oxide semiconductor preferably includes at least one member selected from the group consisting of In, Ga, and Zn, or a composite oxide thereof. More preferably, the oxide semiconductor contains In and Zn, and a composition ratio between Zn and In in the electric resistance layer (represented by ratio of Zn to In, Zn/In) is larger than a composition ratio of Zn/In in the active layer. The Zn/In ratio in the electric resistance layer is preferably greater by 3% or more, and more preferably by 10% or more than the Zn/In ratio in the active layer.

The electric conductivity of the active layer is preferably 10⁻⁴ Scm⁻¹ or more and less than 10² Scm⁻¹ and more preferably 10⁻¹ Scm⁻¹ or more and less than 10² Scm⁻¹. The electric conductivity of the electric resistance layer is preferably 10⁻² Scm⁻¹ or less, and more preferably 10⁻⁹ Scm⁻¹ or more and less than 10⁻³ Scm⁻¹, which is lower than the electric conductivity of the active layer.

In the case where the electric conductivity of the active layer is less than 10⁻⁴ Scm⁻¹, no high mobility is obtained as the field effect mobility, and in the case where the electric conductivity of the active layer is 10² Scm⁻¹ or more, an OFF current increases, and thereby no favorable ON/OFF ratio can be obtained, which is not preferred.

Preferably, a ratio of the electric conductivity of the active layer to the electric conductivity of the electric resistance layer (electric conductivity of active layer/electric conductivity of electric resistance layer) is from 10¹ to 10¹⁰, and more preferably from 10² to 10⁸.

Preferably, a thickness of the electric resistance layer is larger than a thickness of the active layer in a view of drive stability. Preferably, a ratio of the thickness of the electric resistance layer to the thickness of the active layer (thickness of electric resistance layer/thickness of active layer) is more than 1 and 100 or less, and more preferably more than 1 and 10 or less.

Preferably, the substrate is a flexible resin substrate.

Next, the structure of the TFT more preferably used in the invention will be described in detail with reference to the drawings.

1) Structure

FIG. 4 is a schematic diagram showing an example of the reversed stagger structure of the TFT of the invention. In the case where a substrate 1 is composed of a flexible substrate such as a plastic film or the like, the TFT has an insulating layer 6 disposed on one surface of the substrate 1, and on the insulating layer 6, a gate electrode 2, a gate insulating layer 3, an active layer 4-1, and an electric resistance layer 4-2 are stacked. On the surface of the structure thus constructed, a source electrode 5-1 and a drain electrode 5-2 are disposed. The active layer 4-1 borders on the gate insulating layer 3, and the electric resistance layer 4-2 borders on the source electrode 5-1 and the drain electrode 5-2. The compositions of the active layer 4-1 and electric resistance layer 4-2 are determined so that the electric conductivity of the active layer 4-1 is higher than that of the electric resistance layer 4-2 when no voltage is applied to the gate electrode. Incidentally, for the active layer, oxide semiconductors disclosed in JP-A No. 2006-165529, e.g., In—Ga—Zn—O-based oxide semiconductors, are used. It is known that in these oxide semiconductors, the higher the concentration of electron carriers is, the higher the electron mobility is. In other words, the higher the electric conductivity is, the higher the electron mobility is.

According to this structure of the invention, when the TFT in the ON state under the condition where voltage is applied to the gate electrode, the active layer which becomes a channel has high electric conductivity. As a result, the field effect mobility of the transistor is increased and a large ON current can be obtained. On the other hand, in the OFF state, the electric resistance layer has a high resistance because of its low electric conductivity, and the OFF current is kept low. Thus, the characteristics of ON-OFF ratio is remarkably improved.

Although it is not shown in the drawing, the point of the invention is to provide a semiconductor layer whose electric conductivity closer to the gate insulating layer is higher than that closer to the source electrode and the drain electrode. As long as this condition is achieved, the means for achieving this is not limited to providing a plurality of semiconductor layers as shown in FIG. 1. The electric conductivity may be changed continuously.

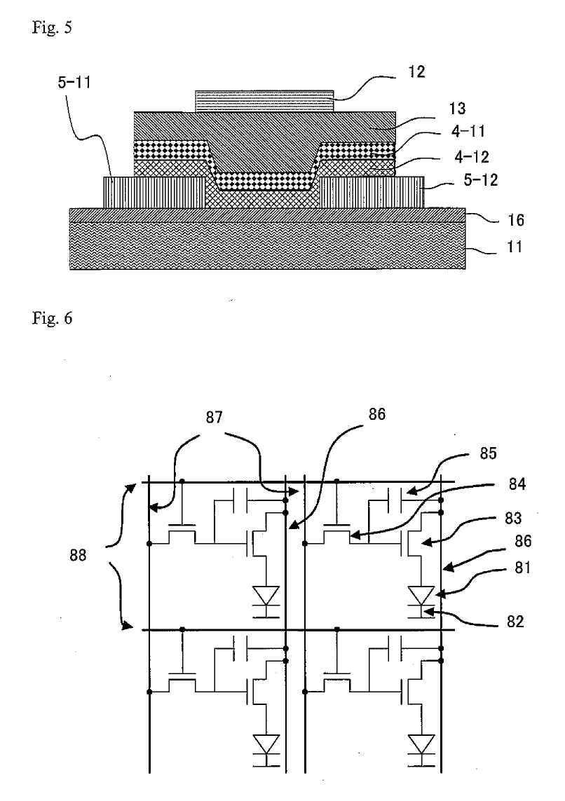

FIG. 5 is a schematic diagram showing an example of the top gate structure of the TFT according to the invention. In the case where a substrate 11 is composed of a flexible substrate such as a plastic film or the like, the TFT has an insulating layer 16 disposed on one surface of the substrate 11, a source electrode 5-11 and a drain electrode 5-12 are provided on the insulating layer, an electric resistance layer 4-12 and an active layer 4-11 are stacked, and then a gate insulating layer 13 and a gate electrode 12 are provided. Similar to the case of the reversed stagger structure, the active layer 4-11 (which is a high-electric conductivity layer) borders on the gate insulating layer 13, and the electric resistance layer 4-12 (which is a low-electric conductivity layer) borders on the source electrode 5-11 and the drain electrode 5-12. The compositions of the active layer 4-11 and electric resistance layer 4-12 are determined so that the electric conductivity of the active layer 4-11 is higher than that of the electric resistance layer 4-12 when no voltage is applied to the gate electrode.

2) Electric Conductivity

Now, the electric conductivity of the active layer and the electric resistance layer in association with the invention will be explained.

The electric conductivity is a physical property which indicates how much electricity a substance can conduct. When a carrier concentration of a substance is denoted by n, a carrier mobility is denoted by μ, and an electric elementary quantity is denoted by e, the electric conductivity σ of the substance is expressed as follows.

σ=neμ

When the active layer or the electric resistance layer is composed of an n-type semiconductor, the carrier is an electron. In this case, the carrier concentration refers to the concentration of electron carriers, and the carrier mobility refers to the electron mobility. Conversely, when the active layer or the electric resistance layer is a p-type semiconductor, the carrier is a hole. In this case, the carrier concentration refers to the concentration of hole carriers, and the carrier mobility refers to the hole mobility. Further, the carrier concentration and carrier mobility of a substance can be determined by Hall measurements.

<Method of Determining Electric Conductivity>

The electric conductivity of a film can be determined by measuring the sheet resistance of the film, provided that the thickness of the film is known. The electric conductivity of a semiconductor changes depending on the temperature, and the electric conductivity cited herein refers to the electric conductivity at room temperature (20° C.).

3) Gate Insulating Layer

For the gate insulating layer, an insulator such as SiO₂, SiNₓ, SiON, Al₂O₃, Y₂O₃, Ta₂O₅, HfO₂ and the like, or a mixed crystal compound containing at least two of these is used. Also, a polymeric insulator such as polyimide may be used for the gate insulating layer.

It is preferable that the gate insulating layer has a thickness of from 10 nm to 10 μm. To reduce the leak current and raise the voltage resistance, it is required to make the gate insulating layer thicker to a certain extent. However, an increase in the thickness of the gate insulating layer results in a rise in the voltage needed for driving the TFT. Therefore, it is preferable that the thickness of the gate insulating layer is from 50 nm to 1000 nm for an inorganic insulator, and from 0.5 μm to 5 μm for a polymeric insulator. Especially, it is particularly preferable to use an insulator with a high dielectric constant, such as HfO₂, for the gate insulating layer, because then the TFT can be driven with low voltage even when it is made thicker.

4) Active Layer and Electric Resistance Layer

For the semiconductor layer including the active layer and the electric resistance layer in this invention, it is preferable to use an oxide semiconductor. Particularly, an amorphous oxide semiconductor is preferable. Films of oxide semiconductors, particularly amorphous oxide semiconductors, can be formed at a low temperature, and so can be prepared on a flexible resin substrate such as plastic. Preferable amorphous oxide semiconductors which can be prepared at a low temperature include an oxide containing In, an oxide containing In and Zn, and an oxide containing In, Ga and Zn, as disclosed in JP-A No. 2006-165529. Considering their compositional structures, it is known that amorphous oxide semiconductors of InGaO₃(ZnO)ₘ (m is a natural number less than 6) are preferable. These oxide semiconductors are n-type semiconductors, in which electrons serve as carriers. Of course, p-type oxide semiconductors such as ZnO/Rh₂O₃, CuGaO₂, and SrCu₂O₂ may be used for the semiconductor layer.

Specifically, an amorphous oxide semiconductor according to the invention preferably has a constitution including In—Ga—Zn—O. The amorphous oxide semiconductor is preferably an amorphous oxide semiconductor with a composition of InGaO₃(ZnO)ₘ (m is a natural number less than 6) in a crystalline state. Particularly, InGaZnO₄ is more preferable. An amorphous oxide semiconductor of such composition has a feature that the electron mobility tends to increase with an increase in the electric conductivity. In addition, as to the control of the electric conductivity, it is disclosed in JP-A No. 2006-165529 that the electric conductivity can be controlled by controlling the partial pressure of oxygen during the film formation.

<Electric Conductivity of Active Layer and Electric Resistance Layer>

The active layer of the invention is characterized in that it is closer to the gate insulating layer, and the electric conductivity thereof is higher than that of the electric resistance layer which is closer to the source electrode and the drain electrode.

The ratio of the electric conductivity of the active layer to the electric conductivity of the electric resistance layer (i.e., electric conductivity of active layer/electric conductivity of electric resistance layer) is preferably from 10¹ to 10¹⁰, and more preferably from 10² to 10⁸. The electric conductivity of the active layer is preferably 10⁻⁴ Scm⁻¹ or more and less than 10² Scm⁻¹, and more preferably 10⁻¹ Scm⁻¹ or more and less than 10² Scm⁻¹. The electric conductivity of the electric resistance layer is preferably 10⁻² Scm⁻¹ or less, and more preferably 10⁻⁹ Scm⁻¹ or more and less than 10⁻³ Scm⁻¹.

<Thickness of Active Layer and Electric Resistance Layer>

It is preferable that the electric resistance layer is thicker than the active layer. More preferably, the ratio of a thickness of the electric resistance layer to that of the active layer is more than 1 and 100 or less, and even more preferably the ratio is more than 1 and 10 or less.

Preferably, the thickness of the active layer is from 1 nm to 100 nm, and more preferably, from 2.5 nm to 30 nm. Preferably, the thickness of the electric resistance layer is from 5 nm to 500 nm, and more preferably, from 10 nm to 100 nm.

The use of the semiconductor layer including the active layer and the electric resistance layer arranged as described above achieves a TFT characterized by an ON-OFF ratio of 10⁶ or higher and high mobility of 10 cm²/V/sec or higher.

<Means for Adjusting Electric Conductivity>

The electric conductivity of the semiconductor layer according to the present invention is adjusted so that, as described above, the electric conductivity of a part of the semiconductor layer closer to the gate insulating layer (active layer) becomes larger than the electric conductivity of a part of the semiconductor layer closer to the source electrode or the drain electrode (electric insulating layer).

In the case where the semiconductor layer is composed of an oxide semiconductor, the means for adjusting the electric conductivity are what are described in the following items (1) to (4).

(1) Adjustment by Oxygen Defect

It is known that when an oxygen vacancy is made in an oxide semiconductors, a carrier electron is generated, which results in an increase in electric conductivity. Hence, the electric conductivity of an oxide semiconductor can be controlled by adjusting the quantity of oxygen defects. Specifically, means for controlling the quantity of oxygen defects include adjusting the partial pressure of oxygen during the time of film formation, and oxygen concentration and treatment time of an after-treatment after the film formation. Specifically, examples of this after-treatment include heat treatment at a temperature of 100° C. or higher, processing by oxygen plasma, and UV ozone treatment. Among these, the method involving controlling the partial pressure of oxygen during the time of film formation is preferable in view of its productivity. It has been disclosed in JP-A No. 2006-165529 that the electric conductivity of an oxide semiconductor can be controlled by adjusting the partial pressure of oxygen during the time of film formation, and therefore this method is usable.

(2) Adjustment by Composition Ratio

It has been known that the electric conductivity can be changed by changing the composition ratio of metals of an oxide semiconductor. For instance, it has been disclosed in JP-A No. 2006-165529 that in the case of InGaZn₁₋ₓMgₓO₄, the electric conductivity lowers with an increase in the percentage of Mg. In addition, it has been reported that the electric conductivity of oxides of (In₂O₃)₁₋ₓ(ZnO)ₓ lowers with an increase in the percentage of Zn when the Zn/In ratio is 10% or higher (“TOMEI DOUDENMAKU NO SINTENKAI II (Developments of Transparent Conductive Films II)”, pages 34-35, CMC Publishing CO., LTD.). Specifically, methods for changing the composition ratio, for example, in the case of a method of forming a film by sputtering include a means using targets with different composition ratios. Alternatively, multiple targets may be co-sputtered, changing the composition ratio of the resultant film by individually adjusting the sputtering rates for the targets.

(3) Adjustment by Impurities

It has been disclosed in JP-A No. 2006-165529 that when elements such as La, Na, Mn, Ni, Pd, Cu, Cd, C, N, and P are selectively added to an oxide semiconductor as an impurity, the concentration of electron carriers can be reduced, and therefore the electric conductivity can be made lower. Methods for adding an impurity include co-vapor deposition of the oxide semiconductor and the impurity, and ion-doping of an oxide semiconductor film which has already been formed with ions of the impurity element.

(4) Adjustment by Oxide Semiconductor Material

While in the above items (1) to (3), the methods of adjusting the electric conductivity of the same oxide semiconductor system have been described, the electric conductivity can be changed by changing the oxide semiconductor material. It is known that the electric conductivity of SnO₂-based oxide semiconductors is lower than In₂O₃-based oxide semiconductors. In such a way, the electric conductivity can be adjusted by changing the oxide semiconductor material. In particular, as the oxide materials having low electric conductivity, oxide insulator materials such as Al₂O₃, Ga₂O₃, ZrO₂, Y₂O₃, Ta₂O₃, MgO, HfO₃, and the like are known, and it is possible to use these materials.

As the means for adjusting the electric conductivity, the methods stated in the above (1) to (4) may be used independently or in combination.

<Method of Forming Active Layer and Electric Resistance Layer>

As the methods for forming a film of the active layer and the electric resistance layer, it is suitable to adopt a vapor-phase film forming method using, as a target, a polycrystalline sintered compact of an oxide semiconductor. Among the vapor-phase film forming methods, sputtering method and pulsed laser deposition method (PLD method) are adequate. For mass production, sputtering method is preferable.

For instance, by an RF radio frequency magnetron sputtering deposition method, a film can be formed while controlling the vacuum level and flow rate of oxygen. The higher the flow rate of oxygen is, the lower the electric conductivity can be made.

It can be verified by conventional X-ray diffraction that the resultant film is an amorphous film.

The thickness of the film can be determined by contact stylus-type surface profile measurement. The composition ratio can be determined by RBS analysis (Rutherford Backscattering Spectrometry).

5) Gate Electrode

According to the invention, the following materials are among those which are preferable for the gate electrode: a metal such as Al, Mo, Cr, Ta, Ti, Au or Ag, an alloy such as Al—Nd or APC; a metal oxide electric conductive film of e.g., tin oxide, zinc oxide, indium oxide, indium-tin oxide (ITO), or indium-zinc oxide (IZO); an organic electric conductive compound such as polyaniline, polythiophene, or polypyrrole; or a mixture thereof.

The thickness of the gate electrode is preferably from 10 nm to 1000 nm.

The method of forming the electrode is not particularly limited. The gate electrode can be formed on the substrate according to a method which is appropriately selected from among wet methods such as a printing method and a coating method, physical methods such as a vacuum deposition method, a sputtering method and an ion plating method, chemical methods such as a CVD (chemical vapor deposition) and plasma CVD method, and the like in consideration of the suitability with the material described above. For example, when ITO is selected, the gate electrode can be formed according to a direct current or high frequency sputtering method, a vacuum deposition method, or an ion plating method. Further, in the case where an organic electric conductive compound is selected as the material of the gate electrode, the gate electrode can be formed according to a wet film-forming method.

6) Source Electrode and Drain Electrode

According to the invention, the following are suitable for the material of the source electrode and the drain electrode: metals such as Al, Mo, Cr, Ta, Ti, Au and Ag; alloys such as Al—Nd and APC; metal oxide electric conductive films of, for example, tin oxide, zinc oxide, indium oxide, indium-tin oxide (ITO) and indium-zinc oxide (IZO); and organic electric conductive compounds such as polyaniline, polythiophene and polypyrrole, and mixtures thereof.

The thickness of the source electrode and the drain electrode is preferably from 10 nm to 1000 nm.

The method of forming the electrodes is not particularly limited. The electrodes can be formed on the substrate according to a method which is appropriately selected from among wet methods such as a printing method and a coating method, a physical methods such as a vacuum deposition method, a sputtering method and an ion plating method, a chemical methods such as a CVD and plasma CVD method, and the like in consideration of the suitability with the material described above. For example, when ITO is selected, the electrodes can be formed according to a direct current or high frequency sputtering method, a vacuum deposition method, an ion plating method, etc. Further, in the case where an organic electric conductive compound is selected as the material of the source electrode and the drain electrode, the electrode can be formed according to a wet film-forming method.

8) Insulating Film

If necessary, an insulating film may be provided on TFT.

The insulating film has a function to protect the semiconductor layer (active layer and resistance layer) from deterioration by air, and to insulate an electronic device formed on TFT from the TFT.

Specific examples of materials for the insulating layer include metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one co-monomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the insulating layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD) method, a laser CVD method, a thermal CVD method, a gas source CVD method, a coating method, a printing method, or a transfer method may be applied.

8) After-Treatment

If necessary, thermal treatment may be conducted as an after-treatment for TFT. The thermal treatment is performed under air or nitrogen environment at 100° C. or higher. The thermal treatment may be conducted after forming the semiconductor layer or at a last step of TFT fabrication steps. The thermal treatment has results in that a fluctuation of TFT properties within a set of TFT is prevented, and drive stability is improved.

3. Organic EL Element

Hereinafter, the organic EL element of the invention is described in detail.

The light-emitting element of the invention has a cathode and an anode on a substrate, and an organic layer containing an organic light-emitting layer (hereinafter, sometimes simply referred to as a “light-emitting layer”) between the two electrodes. Due to the nature of a light-emitting element, at least one electrode of the anode and the cathode is preferably transparent.

As an integration pattern of the organic compound layer according to the present invention, it is preferred that the layer includes a hole transporting layer, a light-emitting layer, and an electron transport layer integrated in the order from the anode side. Moreover, a hole injection layer is provided between the hole transporting layer and the anode, and/or an electron transporting intermediate layer is provided between the light-emitting layer and the electron transport layer. In addition, a hole transporting intermediate layer may be provided between the light-emitting layer and the hole transporting layer, and similarly, an electron injection layer may be provided between the cathode and the electron transport layer.

Further, each of the layers may be composed of plural secondary layers.

The respective layers constituting the organic compound layer can be suitably formed in accordance with any of a dry film-forming method such as a vapor deposition method, or a sputtering method; a transfer method; a printing method; a coating method; an ink-jet method; a spray method; or the like.

Next, the components constituting the light-emitting material of the present invention will be described in detail.

(Substrate)

The substrate to be applied in the invention is preferably one which does not scatter or attenuate light emitted from the organic compound layer. Specific examples of materials for the substrate include inorganic materials such as zirconia-stabilized yttrium (YSZ), glass and the like; polyesters such as polyethylene terephthalate, polybutylene phthalate, and polyethylene naphthalate; and organic materials such as polystyrene, polycarbonate, polyethersulfone, polyarylate, polyimide, polycycloolefin, norbornene resin, polychlorotrifluoroethylene, and the like.

For instance, when glass is used as the substrate, non-alkali glass is preferably used with respect to the quality of material in order to decrease ions eluted from the glass. In the case of employing soda-lime glass, it is preferred to use glass on which a barrier coat of silica or the like has been applied. In the case of employing an organic material it is preferred to use a material excellent in heat resistance, dimensional stability, solvent resistance, electric insulation performance, and workability.

There is no particular limitation as to the shape, the structure, the size or the like of the substrate, but it may be suitably selected according to the application, purposes and the like of the light-emitting element. In general, a plate-like substrate is preferred as the shape of the, substrate. A structure of the substrate may be a monolayer structure or a laminated structure. Furthermore, the substrate may be formed from a single member or two or more members.

Although the substrate may be transparent and colorless, or transparent and colored, it is preferred that the substrate is transparent and colorless from the viewpoint that the substrate does not scatter or attenuate light emitted from the organic light-emitting layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In the case of applying a thermoplastic substrate, a hard-coat layer or an under-coat layer may be further provided as needed.

(Anode)

The anode may generally be any material as long as it has a function as an electrode for supplying holes to the organic compound layer, and there is no particular limitation as to the shape, the structure, the size or the like. However, it may be suitably selected from among well-known electrode materials according to the application and purpose of the light-emitting element. As mentioned above, the anode is usually provided as a transparent anode.

Materials for the anode preferably include, for example, metals, alloys, metal oxides, electric conductive compounds, and mixtures thereof. Specific examples of the anode materials include electric conductive metal oxides such as tin oxides doped with antimony, fluorine or the like (ATO and FTO), tin oxide, zinc oxide, indium oxide, indium tin oxide (ITO), and indium zinc oxide (IZO); metals such as gold, silver, chromium, and nickel; mixtures or laminates of these metals and the electric conductive metal oxides; inorganic electric conductive materials such as copper iodide and copper sulfide; organic electric conductive materials such as polyaniline, polythiophene, and polypyrrole; and laminates of these inorganic or organic electric conductive materials with ITO. Among these, the electric conductive metal oxides are preferred, and particularly, ITO is preferable in view of productivity, high electric conductivity, transparency and the like.

The anode may be formed on the substrate in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the anode. For instance, when ITO is selected as a material for the anode, the anode may be formed in accordance with a DC or high-frequency sputtering method, a vacuum deposition method, an ion plating method or the like.

In the organic electroluminescence element of the present invention, a position at which the anode is to be formed is not particularly limited, and it may be suitably selected according to the application and purpose of the light-emitting element. However, the anode is preferably formed on the substrate. In this case, the anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, or a lift-off method or a printing method may be applied.

A thickness of the anode may be suitably selected according to the material constituting the anode and is therefore not definitely decided, but it is usually in a range of from 10 nm to 50 μm, and preferably from 50 nm to 20 μm.

A value of electric resistance of the anode is preferably 10³ Ω/□ or less, and more preferably 10² Ω/□ or less. In the case where the anode is transparent, it may be either transparent and colorless, or transparent and colored. For extracting luminescence from the transparent anode side, it is preferred that a light transmittance of the anode is 60% or higher, and more preferably 70% or higher.

Concerning transparent anodes, there is a detailed description in “TOUMEI DENNKYOKU-MAKU NO SHINTENKAI (Novel Developments in Transparent Electrode Films)” edited by Yutaka Sawada, published by C.M.C. in 1999, the contents of which are incorporated by reference herein. In the case where a plastic substrate having a low heat resistance is applied, it is preferred that ITO or IZO is used to obtain a transparent anode prepared by forming the film thereof at a low temperature of 150° C. or lower.

(Cathode)

The cathode may generally be any material as long as it has a function as an electrode for injecting electrons to the organic compound layer, and there is no particular limitation as to the shape, the structure, the size or the like. However it may be suitably selected from among well-known electrode materials according to the application and purpose of the light-emitting element.

Materials constituting the cathode include, for example, metals, alloys, metal oxides, electric conductive compounds, and mixtures thereof. Specific examples thereof include alkali metals (e.g., Li, Na, K, Cs or the like), alkaline earth metals (e.g., Mg, Ca or the like), gold, silver, lead, aluminum, sodium-potassium alloys, lithium-aluminum alloys, magnesium-silver alloys, rare earth metals such as indium, and ytterbium, and the like. They may be used alone, but it is preferred that two or more of them are used in combination from the viewpoint of satisfying both stability and electron inject-ability.

Among these, as the materials for constituting the cathode, alkaline metals or alkaline earth metals are preferred in view of electron inject-ability, and materials containing aluminum as a major component are preferred in view of excellent preservation stability.

The term “material containing aluminum as a major component” refers to a material constituted by aluminum alone; alloys comprising aluminum and 0.01% by weight to 10% by weight of an alkaline metal or an alkaline earth metal; or the mixtures thereof (e.g., lithium-aluminum alloys, magnesium-aluminum alloys and the like).

Regarding materials for the cathode, they are described in detail in JP-A Nos. 2-15595 and 5-121172, the contents of which are incorporated by reference herein.

A method for forming the cathode is not particularly limited, but it may be formed in accordance with a well-known method. For instance, the cathode may be formed in accordance with a method which is appropriately selected from among wet methods such as printing methods, coating methods and the like; physical methods such as vacuum deposition methods, sputtering methods, ion plating methods and the like; and chemical methods such as CVD and plasma CVD methods and the like, in consideration of the suitability to a material constituting the cathode. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, or a lift-off method or a printing method may be applied.

In the present invention, a position at which the cathode is to be formed is not particularly limited, and it may be formed on either the whole or a part of the organic compound layer.

Furthermore, a dielectric material layer made of fluorides, oxides or the like of an alkaline metal or an alkaline earth metal may be inserted between the cathode and the organic compound layer with a thickness of 0.1 nm to 5 nm. The dielectric layer may be considered to be a kind of electron injection layer. The dielectric material layer may be formed in accordance with, for example, a vacuum deposition method, a sputtering method, an ion-plating method or the like.

A thickness of the cathode may be suitably selected according to materials for constituting the cathode and is therefore not definitely decided, but it is usually in a range of from 10 nm to 5 μm, and preferably from 50 nm to 1 μm.

Moreover, the cathode may be transparent or opaque. The transparent cathode may be formed by preparing a material for the cathode with a small thickness of 1 nm to 10 nm, and further laminating a transparent electric conductive material such as ITO or IZO thereon.

(Organic Compound Layer)

The organic compound layer according to the present invention is to be described.

The organic EL element according to the present invention has at least one organic compound layer including a light-emitting layer. An organic compound layer apart from the light-emitting layer comprises a hole transporting layer, an electron transport layer, a hole blocking layer, an electron blocking layer, a hole injection layer, an electron injection layer and the like as described above.

In the organic EL element of the present invention, the respective layers constituting the organic compound layer can be suitably formed in accordance with any of a dry film-forming method such as a vapor deposition method, or a sputtering method; a wet film-forming method; a transfer method; a printing method; an ink-jet method; or the like.

(Light-Emitting Layer)

The organic light-emitting layer is a layer having functions of receiving holes from the anode, the hole injection layer, or the hole transporting layer, and receiving electrons from the cathode, the electron injection layer, or the electron transport layer, and providing a field for recombination of the holes with the electrons to emit light, when an electric field is applied to the layer.

The light-emitting layer according to the present invention may contain only a light-emitting material, or may be a mixture layer containing a light-emitting dopant and a host material. The light-emitting dopant may be a fluorescent light-emitting material or a phosphorescent light-emitting material, and may be a plurality of those compounds. Preferably, the host material is a charge-transporting material. The host material may be one or a plurality of compounds. For example, a mixture of a hole-transporting host material and an electron-transporting host material is preferable. Further, a material which does not emit light nor transport any charge may be contained in the light-emitting layer.

The light-emitting layer may be a single layer or a plurality of layers, wherein the layers may emit light with respectively different colors.

In the present invention, any of a fluorescent light-emitting material and a phosphorescent light-emitting material may be used as a light-emitting dopant.

The light-emitting layer of the present invention may contain two or more types of light-emitting dopants for improving color purity and expanding the wavelength region of emitted light. It is preferred that the light-emitting dopant in the present invention is one satisfying a relationship between the above-described host material and the light-emitting dopant of 1.2 eV>the difference of Ip between host material and light-emitting dopant (ΔIp)>0.2 eV and/or 1.2 eV>the difference of Ea between host material and light-emitting dopant (ΔEa)>0.2 eV in view of drive durability.

<<Phosphorescent Light-Emitting Dopant>>

Examples of the phosphorescent light-emitting dopants generally include complexes containing a transition metal atom or a lanthanoid atom.

For instance, although the transition metal atom is not limited, it is preferably ruthenium, rhodium, palladium, tungsten, rhenium, osmium, iridium, gold, silver, copper or platinum; more preferably rhenium, iridium, or platinum, and even more preferably iridium or platinum.

Examples of the lanthanoid atom include lanthanum, cerium, praseodymium, neodymium, samarium, europium, gadolinium, terbium, dysprosium, holmium, erbium, thulium, ytterbium, and lutetium, and among these lanthanoid atoms, neodymium, europium, and gadolinium are preferred.

Examples of ligands in the complex include the ligands described, for example, in “Comprehensive Coordination Chemistry” authored by G. Wilkinson et al., published by Pergamon Press Company in 1987; “Photochemistry and Photophysics of Coordination Compounds” authored by H. Yersin, published by Springer-Verlag Company in 1987; and “YUHKI KINZOKU KAGAKU-KISO TO OUYOU- (Organometallic Chemistry-Fundamental and Application-)”authored by Akio Yamamoto, published by Shokabo Publishing Co., Ltd. in 1982.

Specific examples of the ligand include halogen ligand (preferably, chlorine ligand), aliphatic carbon ring ligand (for example, having preferably 5 to 30 carbon atoms, more preferably 6 to 30 carbon atoms, further preferably 6 to 20 carbon atoms, and particularly preferably 6 to 12 carbon atoms, such as cyclopentadienyl anion, benzene anion, naphthyl anion, or the like), nitrogen-containing heterocyclic ligand (for example, having preferably 5 to 30 atoms, more preferably 6 to 30 carbon atoms, further preferably 6 to 20 carbon atoms, and particularly preferably 6 to 12 carbon atoms, for example, phenyl pyridine, benzoquinoline, quinolinol, bipyridyl, phenanthrorine, or the like), diketone ligand (for example, acetyl acetone, or the like), carboxylic acid ligand (for example, having preferably 2 to 30 carbon atoms, more preferably 2 to 20 carbon atoms, and further preferably 2 to 16 carbon atoms, such as acetic acid ligand, or the like), alcoholato ligand (for example, having preferably 1 to 30 carbon atoms, more preferably 1 to 20 carbon atoms, and further preferably 6 to 20 carbon atoms, such as phenolate ligand, or the like), silyloxy ligand (for example, having preferably 3 to 40 carbon atoms, more preferably 3 to 30 carbon atoms, and further preferably 3 to 20 carbon atoms, such as trimethyl silyloxy ligand, dimethyl-tert-butyl silyloxy ligand, triphenyl silyloxy ligand, or the like), carbon monoxide ligand, isonitrile ligand, cyano ligand, phosphorus ligand (having preferably 3 to 40 carbon atoms, more preferably 3 to 30 carbon atoms, further preferably 3 to 20 carbon atoms, and particularly preferably, 6 to 20 carbon atoms, such as triphenyl phosphine ligand, or the like), thiolato ligand (having preferably 1 to 30 carbon atoms, more preferably 1 to 20 carbon atoms, and further preferably 6 to 20 carbon atoms, such as phenyl thiolato ligand, or the like), and phosphine oxide ligand (having preferably 3 to 30 carbon atoms, more preferably 8 to 30 carbon atoms, and further preferably 18 to 30 carbon atoms, for example, triphenyl phosphine oxide ligand, or the like), and more preferably nitrogen-containing heterocyclic ligand.

The above-described complexes may be either a complex containing one transition metal atom in the compound, or a so-called polynuclear complex containing two or more transition metal atoms wherein different metal atoms may be contained at the same time.

Among these, specific examples of the light-emitting dopants include phosphorescent light-emitting compounds described in patent documents such as U.S. Pat. Nos. 6,303,238B1, and 6,097,147; WO Nos. 00/57676, 00/70655, 01/08230, 01/39234A2, 01/41512A1, 02/02714A2, 02/15645A1, 02/44189A1, and 05/19373A2; JP-A Nos. 2001-247859, 2002-302671, 2002-117978, 2003-133074, 2002-235076, 2003-123982, and 2002-170684; EP No. 1211257; JP-A Nos. 2002-226495, 2002-234894, 2001-247859, 2001-298470, 2002-173674, 2002-203678, 2002-203679, 2004-357791, 2006-256999, 2007-19462, 2007-84635, 2007-96259, etc. Among these, more preferable examples of the light-emitting dopants include Ir complexes, Pt complexes, Cu complexes, Re complexes, W complexes, Rh complexes, Ru complexes, Pd complexes, Os complexes, Eu complexes, Tb complexes, Gd complexes, Dy complexes, and Ce complexes; particularly preferable are Ir complexes, Pt complexes, and Re complexes; and among these, Ir complexes, Pt complexes, and Re complexes each containing at least one coordination mode of metal-carbon bonds, metal-nitrogen bonds, metal-oxygen bonds, and metal-sulfur bonds are preferred. Particularly preferably, Ir complexes, Pt complexes, and Re complexes each containing a tri-dentate or higher poly-dentate ligand are preferred in view of light-emission efficiency, drive durability, color purity and the like.

<<Fluorescent Light-Emitting Dopant>>

Examples of the above-described fluorescent light-emitting dopants generally include benzoxazole, benzimidazole, benzothiazole, styrylbenzene, polyphenyl, diphenylbutadiene, tetraphenylbutadiene, naphthalimide, coumarin, pyran, perinone, oxadiazole, aldazine, pyralidine, cyclopentadiene, bis-styrylanthracene, quinacridone, pyrrolopyridine, thiadiazolopyridine, cyclopentadiene, styrylamine, aromatic dimethylidene compounds, condensed polycyclic aromatic compounds (anthracene, phenanthroline, pyrene, perylene, rubrene, pentacene and the like), a variety of metal complexes represented by metal complexes of 8-quinolinol, pyromethene complexes or rare-earth complexes, polymer compounds such as polythiophene, polyphenylene or polyphenylenevinylene, organic silanes, and derivatives thereof.

Among these, specific examples of the light-emitting dopants include the following compounds, but it should be noted that the present invention is not limited thereto.

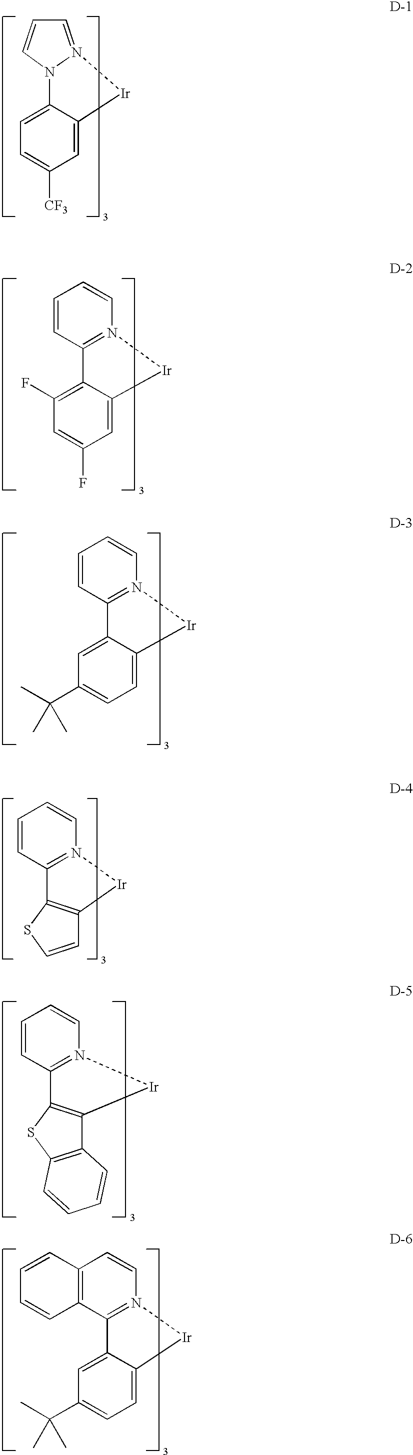

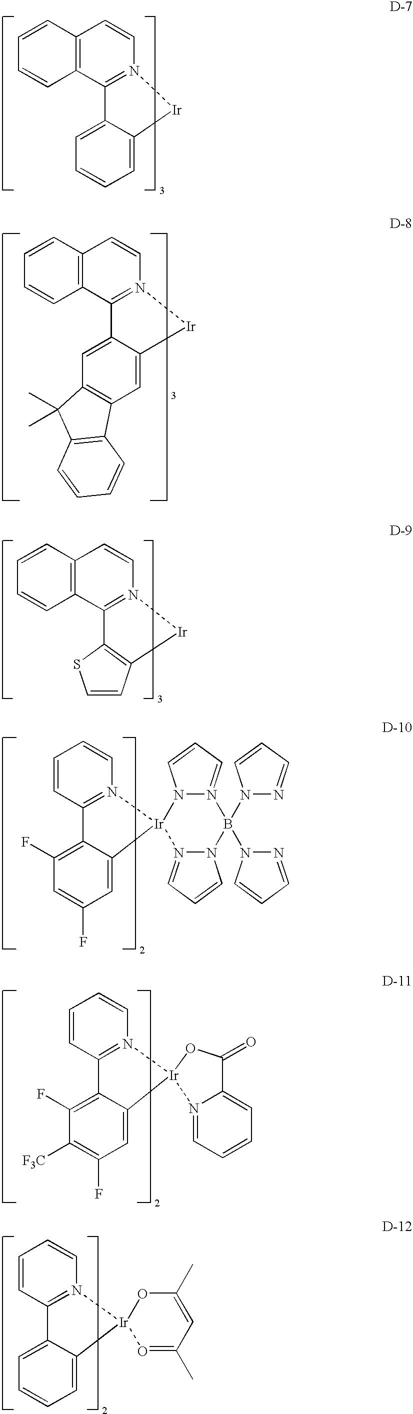

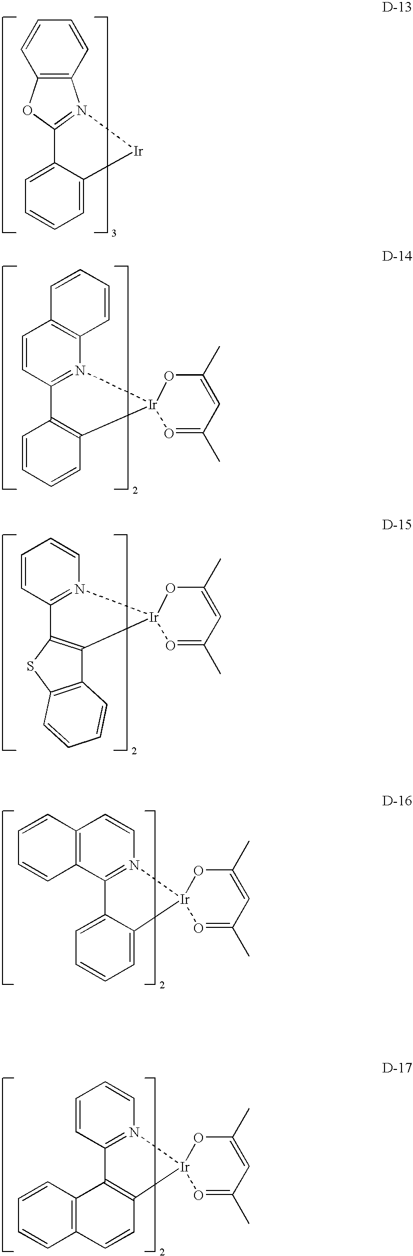

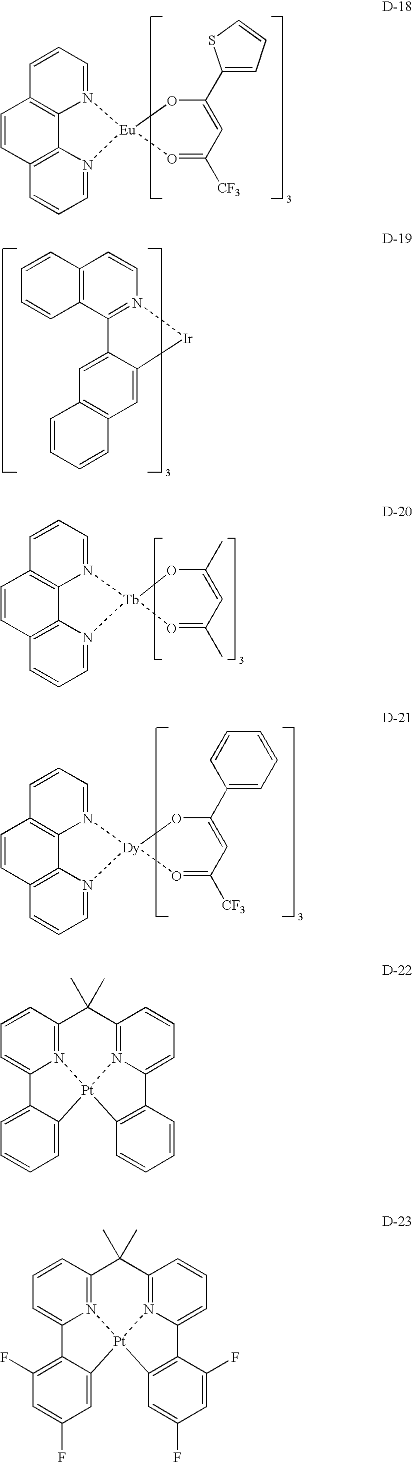

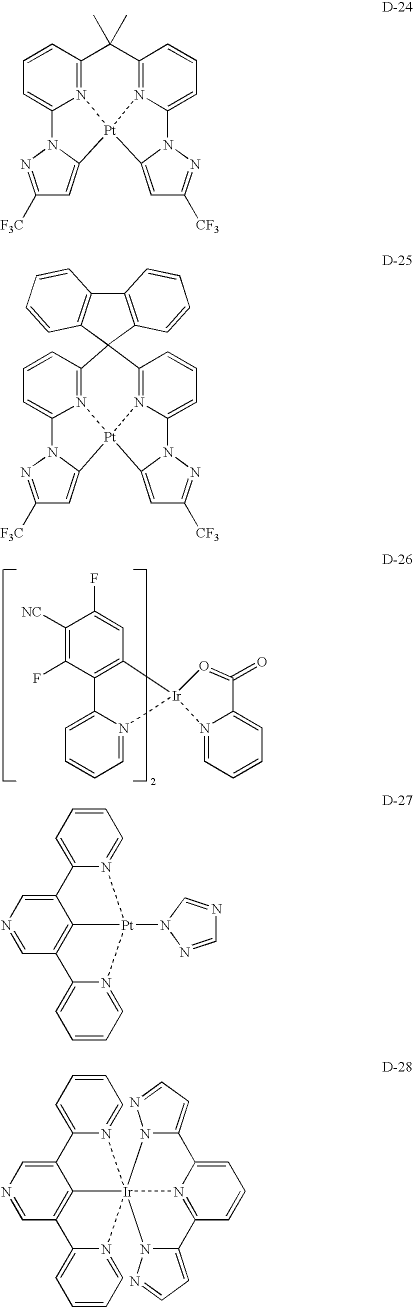

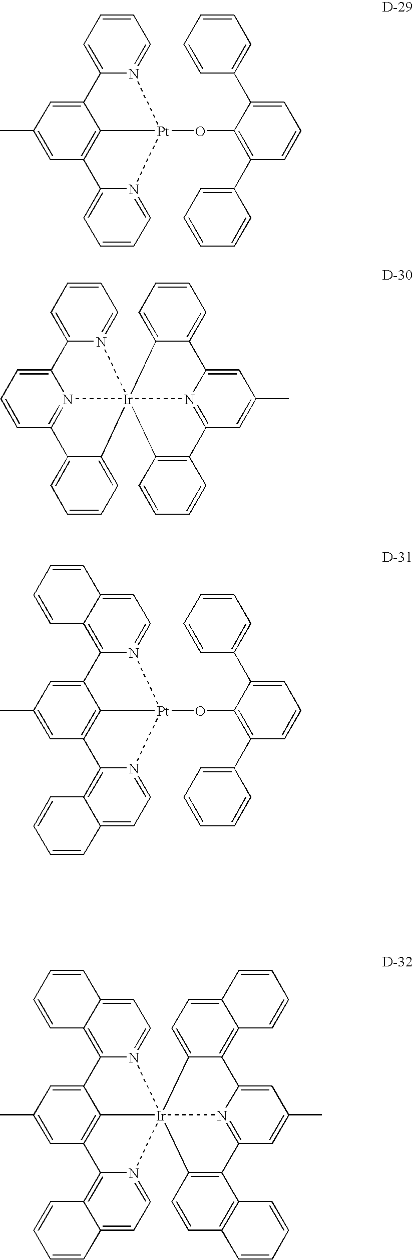

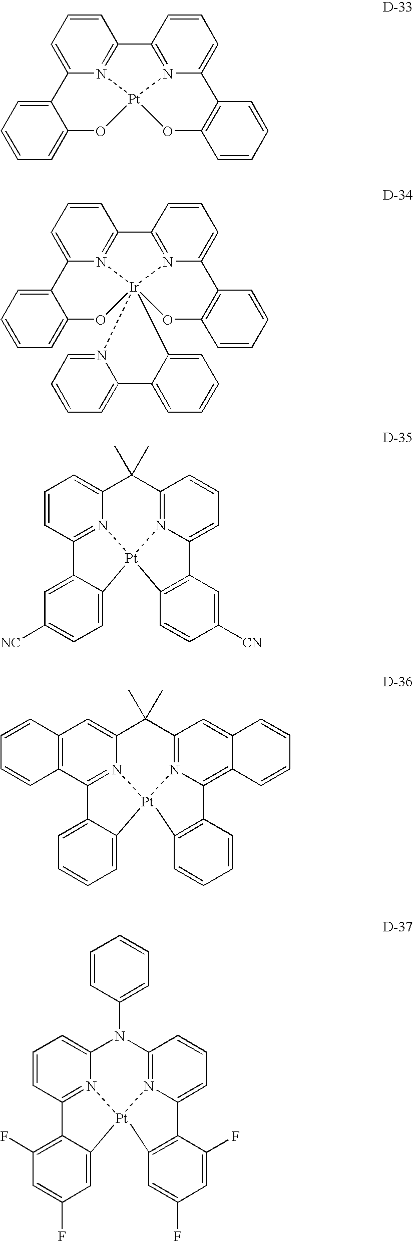

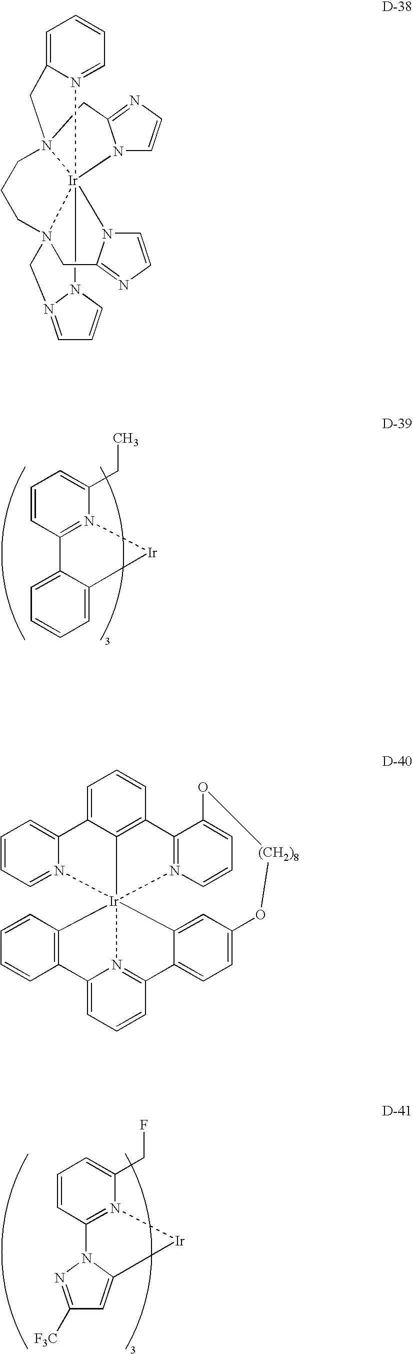

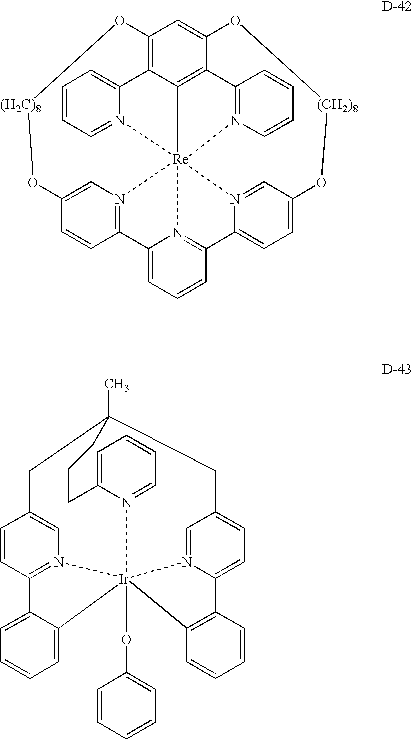

The light-emitting dopant in the light-emitting layer is contained in an amount of from 0.1% by weight to 50% by weight with respect to the total amount of the compounds generally forming the light-emitting layer, but it is preferably contained in an amount of from 1% by weight to 50% by weight, and more preferably in an amount of from 2% by weight to 40% by weight in view of drive durability and external quantum efficiency.

Although a thickness of the light-emitting layer is not particularly limited, 2 nm to 500 nm is usually preferred, and within this range, 3 nm to 200 nm is more preferable, and 5 nm to 100 nm is even more preferred in view of external quantum efficiency.

(Host Material)

As the host materials to be used in the present invention, hole transporting host materials excellent in hole transporting property (referred to as a “hole transporting host” in some cases) and electron transporting host compounds excellent in electron transporting property (referred to as an “electron transporting host” in some cases) may be used.

<<Hole Transporting Host>>

Specific examples of the hole transporting hosts used in the present invention include pyrrole, indole, carbazole, azaindole, azacarbazole, triazole, oxazole, oxadiazole, pyrazole, imidazole, thiophene, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electric conductive high-molecular oligomers such as thiophene oligomers, polythiophenes and the like, organic silanes, carbon films, derivatives thereof, and the like.

Among these, indole derivatives, carbazole derivatives, aromatic tertiary amine compounds, and thiophene derivatives are preferable, and compounds containing a carbazole group in the molecule are preferable. Particularly, compounds containing t-butyl substituted carbazole group are preferred.

<<Electron Transporting Host>>

As the electron transporting host included in the light-emitting layer in the present invention, it is preferred that an electron affinity Ea of the host is from 2.5 eV to 3.5 eV, more preferably from 2.6 eV to 3.4 eV, and even more preferably from 2.8 eV to 3.3 eV in view of improvements in durability and decrease in drive voltage. Furthermore, it is preferred that an ionization potential Ip of the host is 5.7 eV to 7.5 eV, more preferably 5.8 eV to 7.0 eV, and further preferably 5.9 eV to 6.5 eV in view of improvements in drive durability and decrease in drive voltage.

Specific examples of such electron transporting hosts include pyridine, pyrimidine, triazine, imidazole, pyrazole, triazole, oxazole, oxadiazole, fluorenone, anthraquinonedimethane, anthrone, diphenylquinone, thiopyrandioxide, carbodiimide, fluorenylidenemethane, distyrylpyradine, fluorine-substituted aromatic compounds, aromacyclic tetracarboxylic anhydrides such as naphthalene, perylene and the like, phthalocyanine, derivatives thereof (which may form a condensed ring with another ring), and a variety of metal complexes represented by metal complexes of 8-quinolynol derivatives, metal phthalocyanine, and metal complexes having benzoxazole or benzothiazole as the ligand.

Preferable electron transporting hosts are metal complexes, azole derivatives (benzimidazole derivatives, imidazopyridine derivatives and the like), and azine derivatives (pyridine derivatives, pyrimidine derivatives, triazine derivatives and the like). Among these, metal complex compounds are preferred in the present invention in view of durability. As the metal complex compound, a metal complex containing a ligand having at least one nitrogen atom, oxygen atom, or sulfur atom to be coordinated with the metal is more preferable.

Although a metal ion in the metal complex is not particularly limited, a beryllium ion, a magnesium ion, an aluminum ion, a gallium ion, a zinc ion, an indium ion, a tin ion, a platinum ion, or a palladium ion is preferred; more preferable is a beryllium ion, an aluminum ion, a gallium ion, a zinc ion, a platinum ion, or a palladium ion; and further preferable is an aluminum ion, a zinc ion, or a palladium ion.

Although there are a variety of well-known ligands to be contained in the above-described metal complexes, examples thereof include ligands described in “Photochemistry and Photophysics of Coordination Compounds” authored by H. Yersin, published by Springer-Verlag Company in 1987; “YUHKI KINZOKU KAGAKU-KISO TO OUYOU- (Organometallic Chemistry-Fundamental and Application-)” authored by Akio Yamamoto, published by Shokabo Publishing Co., Ltd. in 1982, and the like.

The ligands are preferably nitrogen-containing heterocyclic ligands (having preferably 1 to 30 carbon atoms, more preferably 2 to 20 carbon atoms, and particularly preferably 3 to 15 carbon atoms); and they may be a unidentate ligand or a bi- or higher-dentate ligand. Preferable are bi- to hexa-dentate ligands, and mixed ligands of bi- to hexa-dentate ligands with a unidentate ligand are also preferable.

Examples of the ligands include azine ligands (e.g. pyridine ligands, bipyridyl ligands, terpyridine ligands and the like); hydroxyphenylazole ligands (e.g. hydroxyphenylbenzimidazole ligands, hydroxyphenylbenzoxazole ligands, hydroxyphenylimidazole ligands, hydroxyphenylimidazopyridine ligands and the like); alkoxy ligands (those having preferably 1 to 30 carbon atoms, more preferably 1 to 20 carbon atoms, and particularly preferably 1 to 10 carbon atoms, examples of which include methoxy, ethoxy, butoxy, 2-ethylhexyloxy and the like); aryloxy ligands (those having preferably 6 to 30 carbon atoms, more preferably 6 to 20 carbon atoms, and particularly preferably 6 to 12 carbon atoms, examples of which include phenyloxy, 1-naphthyloxy, 2-naphthyloxy, 2,4,6-trimethylphenyloxy, 4-biphenyloxy and the like); heteroaryloxy ligands (those having preferably 1 to 30 carbon atoms, more preferably 1 to 20 carbon atoms, and particularly preferably 1 to 12 carbon atoms, examples of which include pyridyloxy, pyrazyloxy, pyrimidyloxy, quinolyloxy and the like); alkylthio ligands (those having preferably 1 to 30 carbon atoms, more preferably 1 to 20 carbon atoms, and particularly preferably 1 to 12 carbon atoms, examples of which include methylthio, ethylthio and the like); arylthio ligands (those having preferably 6 to 30 carbon atoms, more preferably 6 to 20 carbon atoms, and particularly preferably 6 to 12 carbon atoms, examples of which include phenylthio and the like); heteroarylthio ligands (those having preferably 1 to 30 carbon atoms, more preferably 1 to 20 carbon atoms, and particularly preferably 1 to 12 carbon atoms, examples of which include pyridylthio, 2-benzimidazolylthio, 2-benzoxazolylthio, 2-benzothiazolylthio and the like); siloxy ligands (those having preferably 1 to 30 carbon atoms, more preferably 3 to 25 carbon atoms, and particularly preferably 6 to 20 carbon atoms, examples of which include a triphenylsiloxy group, a triethoxysiloxy group, a triisopropylsiloxy group and the like); aromatic hydrocarbon anion ligands (those having preferably 6 to 30 carbon atoms, more preferably 6 to 25 carbon atoms, and particularly preferably 6 to 20 carbon atoms, examples of which include a phenyl anion, a naphthyl anion, an anthranyl anion and the like anion); aromatic heterocyclic anion ligands (those having preferably 1 to 30 carbon atoms, more preferably 2 to 25 carbon atoms, and particularly preferably 2 to 20 carbon atoms, examples of which include a pyrrole anion, a pyrazole anion, a triazole anion, an oxazole anion, a benzoxazole anion, a thiazole anion, a benzothiazole anion, a thiophene anion, a benzothiophene anion and the like); indolenine anion ligands and the like. Among these, nitrogen-containing heterocyclic ligands, aryloxy ligands, heteroaryloxy groups, aromatic hydrocarbon anion ligands, aromatic heterocyclic anion ligands or siloxy ligands are preferable, and nitrogen-containing heterocyclic ligands, aryloxy ligands, siloxy ligands, aromatic hydrocarbon anion ligands, or aromatic heterocyclic anion ligands are more preferable.

Examples of the metal complex electron transporting hosts include compounds described, for example, in JP-A Nos. 2002-235076, 2004-214179, 2004-221062, 2004-221065, 2004-221068, 2004-327313 and the like.

In the light-emitting layer of the present invention, it is preferred that the lowest triplet excitation energy T1 of the host material is higher than T1 of the phosphorescent light-emitting material in view of color purity, light-emission efficiency, and drive durability.

Although a content of the host compounds according to the present invention is not particularly limited, it is preferably 15% by weight to 95% by weight with respect to the total amount of the compounds forming the light-emitting layer in view of light-emission efficiency and drive voltage.

(Hole Injection Layer and Hole Transporting Layer)

The hole injection layer and hole transporting layer correspond to layers functioning to receive holes from an anode or from an anode side and to transport the holes to a cathode side. Materials to be introduced into a hole injection layer or a hole transporting layer is not particularly limited, but either of a low molecular compound or a high molecular compound may be used.

As a material for the hole injection layer and the hole transporting layer, it is preferred to contain specifically pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidine compounds, phthalocyanine compounds, porphyrin compounds, thiophene derivatives, organic silane derivatives, carbon, or the like.

An electron-accepting dopant may be introduced into the hole injection layer or the hole transporting layer in the organic EL element of the present invention. As the electron-accepting dopant to be introduced into the hole injection layer or the hole transporting layer, either of an inorganic compound or an organic compound may be used as long as the compound has electron accepting property and a function for oxidizing an organic compound.

Specifically, the inorganic compound includes metal halides, such as iron (III) chloride, aluminum chloride, gallium chloride, indium chloride and antimony pentachloride and the like, and metal oxides, such as vanadium pentaoxide, molybdenum trioxide and the like.

In the case of the organic compounds, compounds having a substituent such as a nitro group, a halogen, a cyano group, a trifluoromethyl group or the like; quinone compounds; acid anhydride compounds; fullerenes; and the like may be preferably applied. Specific examples thereof other than those above include compounds described in patent documents such as JP-A Nos. 6-212153, 11-111463, 11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637, 2005-209643 and the like.

Among these, hexacyanobutadiene, hexacyanobenzene, tetracyanoethylene, tetracyanoquinodimethane, tetrafluorotetracyanoquinodimethane, p-fluoranil, p-chloranil, p-bromanil, p-benzoquinone, 2,6-dichlorobenzoquinone, 2,5-dichlorobenzoquinone, 1,2,4,5-tetracyanobenzene, 1,4-dicyanotetrafluorobenzene, 2,3-dichloro-5,6-dicyanobenzoquinone, p-dinitrobenzene, m-dinitrobenzene, o-dinitrobenzene, 1,4-naphthoquinone, 2,3-dichloronaphthoquinone, 1,3-dinitronaphthalene, 1,5-dinitronaphthalene, 9,10-anthraquinone, 1,3,6,8-tetranitrocarbazole, 2,4,7-trinitro-9-fluorenone, 2,3,5,6-tetracyanopyridine, and fullerene C60 are preferable. Hexacyanobutadiene, hexacyanobenzene, tetracyanoethylene, tetracyanoquinodimethane, tetrafluorotetracyanoquinodimethane, p-fluoranil, p-chloranil, p-bromanil, 2,6-dichlorobenzoquinone, 2,5-dichlorobenzoquinone, 2,3-dichloronaphthoquinone, 1,2,4,5-tetracyanobenzene, 2,3-dichloro-5,6-dicyanobenzoquinone, and 2,3,5,6-tetracyanopyridine are more preferred, and tetrafluorotetracyanoquinodimethane is particularly preferred.

These electron-accepting dopants may be used alone or in a combination of two or more of them. Although an applied amount of these electron-accepting dopants depends on the type of material, 0.01% by weight to 50% by weight of a dopant is preferred with respect to a hole transporting layer material, 0.05% by weight to 20% by weight is more preferable, and 0.1% by weight to 10% by weight is particularly preferred.

A thickness of the hole injection layer and the hole transporting layer is preferably 500 mn or less in view of decrease in drive voltage.

A thickness of the hole-transport layer is preferably from 1 nm to 500 nm, more preferably from 5 nm to 200 nm, and even more preferably from 10 nm to 100 nm. A thickness of the hole injection layer is preferably from 0.1 nm to 200 nm, more preferably from 0.5 nm to 100 nm, and even more preferably from 1 nm to 100 nm.

The hole injection layer and the hole transporting layer may be composed of a monolayered structure comprising one or two or more of the above-mentioned materials, or a multilayer structure composed of plural layers of a homogeneous composition or a heterogeneous compositions.

(Electron Injection Layer and Electron Transport Layer)

An electron injection layer and an electron transport layer are layers having any of functions for receiving electrons from a cathode or a cathode side, and transporting electrons to an anode side. An electron injection material or an electron-transport material to be introduced therein is not particularly limited, but either of a low molecular compound or a high molecular compound may be used.

Specific examples of the materials include pyridine derivatives, quinoline derivatives, pyrimidine derivatives, pyrazine derivatives, phthalazine derivatives, phenanthoroline derivatives, triazine derivatives, triazole derivatives, oxazole derivatives, oxadiazole derivatives, imidazole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyradine derivatives, aromacyclic tetracarboxylic anhydrides such as perylene or naphthalene, phthalocyanine derivatives, metal complexes represented by metal complexes of 8-quinolinol derivatives, metal phthalocyanine, and metal complexes containing benzoxazole, or benzothiazole as the ligand, organic silane derivatives represented by silole, and the like.

The electron injection layer or the electron transport layer in the organic EL element according to the invention may contain an electron donating dopant. As the electron donating dopant introduced in the electron injection layer or the electron transport layer, any material may be used as long as it has an electron-donating property and a property for reducing an organic compound, and alkaline metals such as Li, alkaline earth metals such as Mg, transition metals including rare-earth metals, and reducing organic compounds are preferably used. As the metals, particularly, metals having a work function of 4.2 V or less are preferably applied, and specific examples thereof include Li, Na, K, Be, Mg, Ca, Sr, Ba, Y, Cs, La, Sm, Gd, Yb, and the like. Specific examples of the reducing organic compounds include nitrogen-containing compounds, sulfur-containing compounds, phosphorus-containing compounds, and the like.

In addition, materials described in JP-A Nos. 6-212153, 2000-196140, 2003-68468, 2003-229278 and 2004-342614 may be used.

These electron donating dopants may be used alone or in a combination of two or more of them. An applied amount of the electron donating dopants differs dependent on the types of the materials, but it is preferably from 0.1% by weight to 99% by weight with respect to an electron transport layer material, more preferably from 1.0% by weight to 80% by weight, and even more preferably from 2.0% by weight to 70% by weight.

A thickness of the electron injection layer and the electron transport layer is preferably 500 nm or less in view of decrease in drive voltage.

A thickness of the electron transport layer is preferably from 1 nm to 500 nm, more preferably from 5 nm to 200 nm, and even more preferably from 10 nm to 100 nm. A thickness of the electron injection layer is preferably 0.1 nm to 200 nm, more preferably 0.2 nm to 100 nm, and 0.5 nm to 100 nm is particularly preferred.

The electron injection layer and the electron-transport may be composed of a monolayered structure comprising one or two or more of the above-mentioned materials, or a multilayer structure composed of plural layers of a homogeneous composition or a heterogeneous composition.

(Hole Blocking Layer)

A hole blocking layer is a layer having a function to prevent the holes transported from the anode side to the light-emitting layer from passing through to the cathode side. According to the present invention, a hole blocking layer may be provided as an organic compound layer adjacent to the light-emitting layer on the cathode side.

Examples of the compound constituting the hole blocking layer include an aluminum complex such as BAlq (aluminium (III) bis(2-methyl-8-quinolinato)-4-phenylphenolate), a triazole derivative, a phenanthroline derivative such as BCP (2,9-dimethyl-4,7-diphenyl-1,10-phenanthroline), or the like.

A thickness of the hole blocking layer is preferably from 1 nm to 500 nm, more preferably from 5 nm to 200 nm, and even more preferably from 10 nm to 100 nm.

The hole blocking layer may have either a monolayer structure comprising one or two or more of the above-mentioned materials, or a multilayer structure composed of plural layers of a homogeneous composition or a heterogeneous composition.

(Electron Blocking Layer)

An electron blocking layer is a layer having a function to prevent the electron transported from the cathode side to the light-emitting layer from passing through to the anode side. According to the present invention, an electron blocking layer may be provided as an organic compound layer adjacent to the light-emitting layer on the anode side. Specific examples of the compound constituting the electron blocking layer include compounds explained above as a hole-transporting material.

A thickness of the electron blocking layer is preferably from 1 nm to 500 nm, more preferably from 5 nm to 200 nm, and even more preferably from 10 nm to 100 nm.

The electron blocking layer may have either a monolayer structure comprising one or two or more of the above-mentioned materials, or a multilayer structure composed of plural layers of a homogeneous composition or a heterogeneous composition.

(Driving)

In the organic EL element of the present invention, when a DC (AC components may be contained as needed) voltage (usually 2 volts to 15 volts) or DC is applied across the anode and the cathode, luminescence can be obtained.

For the driving method of the organic EL element of the present invention, driving methods described in JP-A Nos. 2-148687, 6-301355, 5-29080, 7-134558, 8-234685, and 8-241047; Japanese Patent No. 2784615, U.S. Pat. Nos. 5,828,429 and 6,023,308 are applicable.

In the organic EL element of the present invention, the light-extraction efficiency can be improved by various known methods. It is possible to elevate the light-extraction efficiency and to improve the external quantum efficiency, for example, by modifying the surface shape of the substrate (for example by forming fine irregularity pattern), by controlling the refractive index of the substrate, the ITO layer and/or the organic layer, or by controlling the thickness of the substrate, the ITO layer and/or the organic layer.

The organic EL element of the present invention may have a so-called top-emission configuration in which the emitted light is extracted from the anode side.

The organic EL element of the present invention may have a configuration of having an electric charge-generating layer between a plurality of the light-emitting layers for a purpose to enhance light-emission efficiency.

The electric charge-generating layer has a function of generating electric charges (holes or electrons) during an application of an electric field as well as a function of injecting the generated electric charges into a layer adjacent to the electric charge-generating layer.

The electric charge-generating layer is formed by any material as long as it satisfies for the aforementioned functions, and may be formed by a single compound or a plurality of compounds.

Specific examples of the materials for the electric charge-generating layer include electric conductive materials, semi-conductive materials such as doped organic compounds, and electric insulating materials, and materials disclosed in JP-A Nos. 11-329748, 2003-272860 and 2004-39617 are described.

More specific examples thereof include transparent electric conductive materials such as indium tin oxide (ITO) and indium zinc oxide (IZO); fullerenes such as C60; electric conductive organic substances such as thiophene oligomers; electric conductive organic substances such as metal phthalocyanines, non-metal phthalocyanines, metal porphyrins and non-metal porphyrins; metal materials such as Ca, Ag, Al, Mg—Ag alloy and Al—Li alloy; hole conductive materials; electric conductive materials, and mixtures thereof.

Specific examples of the hole conductive material include hole transfer organic materials such as 2-TNATA (4,4′,4′-tris(2-naphthylphenylamino)triphenylamine) or NPD (N,N′-dinaphthyl-N,N′-diphenyl-[1,1′-biphenyl]-4,4′-diamine) doped with oxidants having electron attracting properties such as F4-TCNQ (2,3,5,6-tetra-fluoro-7,7,8,8-tetra-cyano-quinodimethane), TCNQ (tetra-cyano-quinodimethane), or FeCl₃, P-type electric conductive polymers, and P-type semiconductors. Specific examples of the electro-conductive materials include the electron transport organic materials doped with metals or metal compounds having a work function of less than 4.0 eV, N-type electro-conductive polymers, and an N-type semiconductors. Specific examples of the N-type semiconductors include N-type Si, N-type CdS, N-type ZnS and the like. Specific examples of the P-type semiconductors include P-type Si, P-type CdTe, P-type CuO and the like.

Further, the electric charge-generating layer may use an electric insulating material such as V₂O₅.

The electric charge-generating layer can be formed by a single layer or a lamination of a plurality of layers. Specific examples of the laminations of a plurality of layers include a lamination of an electric conductive material such as a transparent conductive material or a metal material and a hole conductive material, or an electric conductive material, and a lamination of the hole conductive material and the electro-conductive material described above, and the like.

Preferably, a film thickness or a material in the electric charge-generating layer can be selected such that a transmittance of visible light is 50% or more. Further, the film thickness is not particularly limited; however, it is preferably from 0.5 nm to 200 nm, more preferably from 1 nm to 100 nm, further preferably from 3 nm to 50 nm and most preferably from 5 nm to 30 nm.

The method of preparing the electric charge-generating layer is not particularly limited, and the above-described method of preparing organic compound layers can also be used.

The electric charge-generating layer is formed between the two or more light-emitting layers. However, a material having a function of injecting an electric charge into layers adjacent thereto may be contained in a region of an anode side or in a region of a cathode side of the electric charge-generating layer. In order to increase injection properties of electrons into layers adjacent at the anode side thereof, electron injection compounds such as BaO, SrO, Li₂O, LiCl, LiF, MgF₂, MgO, and CaF₂ may be laminated at the anode side of the electric charge-generating layer.

Other than the materials according to the contents herein, materials for forming the electron charge generating layer may be selected on the basis of the descriptions in JP-A No. 2003-45676, and U.S. Pat. Nos. 6,337,492, 6,107,734, and 6,872,472.

The organic EL element in the invention preferably may have a resonator structure. For example, on a transparent substrate, a multi-layered film mirror comprising a plurality of stacked films of different reflective indexes, a transparent or semi-transparent electrode, a light-emitting layer, and a metal electrode stacked to each other. The light generated in the light-emitting layer repeats reflection and conducts oscillation between the multi-layered film mirror and the metal electrode as reflection plates.

In another preferred embodiment of the resonator structure, a transparent or semi-transparent electrode and a metal electrode function respectively as reflection plates on a transparent substrate in which light generated in the light-emitting layer repeats reflection and conducts oscillation therebetween.

For forming the resonance structure, an optical channel length determined based on the effective refractive index of two reflection plates, and the refractive index and the thickness for each of the layers between the reflection plates are controlled to optimal values for obtaining a desired resonance wavelength.

A calculation formula in a case of the first embodiment is described in the specification of JP-A No. 9-180883 and a calculation formula in the case of the second embodiment is described in the specification of JP-A No. 2004-127795.

As a method for forming a full color-type organic EL display, there are known, for example, as described in Monthly Display, September 2000, pages 33 to 37, a tricolor light emission method which arranges organic EL elements emitting light corresponding to three primary colors (blue color (B), green color (G), and red color (R)) on a substrate respectively; a white color method which separates white light emitted by an organic EL element for white color emission into three primary colors through a color filter; and a color conversion method which converts a blue light emitted by an organic EL element for blue light emission into red color (R), and green color (G) through a fluorescent dye layer.

Further, by combining a plurality of organic EL elements of different light emission colors obtained by the methods described above, planar light sources of desired emission colors can be obtained. For example, they include a white color light source obtained by combination of blue color and yellow color light emitting elements, and a white color light source obtained by combination of blue, green and red light-emitting elements.

4. Protective Insulating Layer

In the organic EL display of the present invention, the whole organic EL element may be protected by a protective insulating layer. The protective insulating layer has a function decreasing damage to the organic EL element during formation of TFT on the organic EL element, and a function of electrically insulating the organic EL element and the TFT. Furthermore, the protective insulating layer is preferred to have a function to prevent penetration of substances such as moisture and oxygen, which accelerate deterioration of the element, into the element.

Specific examples of materials for the protective insulating layer include metal oxides such as MgO, SiO, SiO₂, Al₂O₃, GeO, NiO, CaO, BaO, Fe₂O₃, Y₂O₃, TiO₂ and the like; metal nitrides such as SiNₓ, SiNₓO_{y} and the like; metal fluorides such as MgF₂, LiF, AlF₃, CaF₂ and the like; polyethylene; polypropylene; polymethyl methacrylate; polyimide; polyurea; polytetrafluoroethylene; polychlorotrifluoroethylene; polydichlorodifluoroethylene; a copolymer of chlorotrifluoroethylene and dichlorodifluoroethylene; copolymers obtained by copolymerizing a monomer mixture containing tetrafluoroethylene and at least one comonomer; fluorine-containing copolymers each having a cyclic structure in the copolymerization main chain; water-absorbing materials each having a coefficient of water absorption of 1% or more; moisture permeation preventive substances each having a coefficient of water absorption of 0.1% or less; and the like.

There is no particular limitation as to a method for forming the protective insulating layer. For instance, a vacuum deposition method, a sputtering method, a reactive sputtering method, an MBE (molecular beam epitaxial) method, a cluster ion beam method, an ion plating method, a plasma polymerization method (high-frequency excitation ion plating method), a plasma CVD) method, a laser CVD method, a thermal CVD method, a gas source CVD method, a coating method, a printing method, or a transfer method may be applied.

Since the upper electrode of the organic EL element and the source electrode or the drain electrode of the driving TFT have to be connected electrically, a contact hole has to be formed in the protective insulating layer. The method of manufacturing the contact hole includes a wet etching method by an etching solution, a dry etching method using plasmas and an etching method by laser.

### 5. Configuration of Pixel-Circuit in Organic EL Display

FIG. 6 is a schematic diagram of a pixel-circuit of an active matrix type organic EL display which uses the TFT according to the invention. In FIG. 6, an organic EL element 81, a drive TFT 83, a switching TFT 84, and a capacitor 85 are wired with a scanning wire 88, signal wire 87, and common wire 86. The circuit of the display according to the invention is not particularly limited to that shown in FIG. 6. A circuit which is conventionally known in the art may be applied as-is.

(Applications)

An organic EL display according to the invention has such wide ranging applications as a mobile phone display, a personal digital assistant (PDA), a computer display, a car information display, a TV monitor, and general illumination.

All publications, patent applications, and technical standards mentioned in this specification are herein incorporated by reference to the same extent as if each individual publication, patent application, or technical standard was specifically and individually indicated to be incorporated by reference.

### EXAMPLES

In the following, the organic EL display of the invention will be described based on the examples, but it should be noted that the invention is not limited to these examples.

### Example 1

### 1. Preparation of Organic EL Display

### 1-1. Preparation of Organic EL Display No. 1

An organic EL display having a configuration shown in FIG. 1 was prepared.

(Preparation of Organic EL Element Part)

1) Formation of Lower Electrode

On a glass substrate (#1737, manufactured by Corning), indium-tin oxide (which is referred to hereinafter as ITO) was deposited at a thickness of 150 nm to form an anode.

2) Formation of Organic Layer

After cleaning, a hole injection layer, a hole transporting layer, a light-emitting layer, a hole blocking layer, an electron transport layer and an electron injection layer were disposed in this order.

The composition of each layer is as follows. Each layer was provided by resistance heating vacuum deposition.

Hole injection layer: 4,4′,4″-tris(2-naphthylphenylamino)triphenylamine (which is referred to as 2-TNATA), a thickness of 140 nm.

Hole transporting layer: N,N′-dinaphthyl-N,N′-diphenyl-[1,1′-biphenyl]-4,4′-diamine (which is referred to as α-NPD), at a thickness of 10 nm.

Light-emitting layer: a layer containing CBP and Ir(ppy)₃, wherein an amount of Ir(ppy)₃ was 5% by weight with respect to CBP, at a thickness of 20 nm.

Hole blocking layer: aluminium (III) bis(2-methyl-8-quinolinato)-4-phenylphenolate (which is referred to as BAlq), at a thickness of 10 nm.

Electron transport layer: tris(8-hydroxyquinolinato) aluminum (which is referred to as Alq3), at a thickness of 20 nm.

Electron injection layer: lithium fluoride (LiF), at a thickness of 1 nm.

3) Formation of Upper Electrode

Patterning was performed using a shadow mask so that the size of the element became 2 mm'2 mm, and aluminum metal (Al) was deposited at a thickness of 100 am to form a cathode.

(Preparation of Protective Insulating Layer)

On the upper electrode, as a protective insulating layer, a SiON layer with a thickness of 500 nm was formed by an ion plating method. After forming the layer, a contact hole was formed by a laser beam.

(Preparation of Driving TFT Part)

1) Source Electrode and Drain Electrode p As a source electrode and a drain electrode, molybdenum (Mo) with a thickness of 40 nm and ITO with a thickness of 40 nm were deposited by an RF magnetron sputtering vacuum deposition method. Patterning of the source electrode and drain electrode was performed using a shadow mask during sputtering. In this process, a gap between the source electrode and the drain electrode was formed to give a channel length (L) of 200 μm and a channel width (W) of 1000 μm. The electrodes were formed to have a configuration in which the drain electrode and the upper electrode (cathode) of the organic EL element are electrically connected through the contact hole.

2) Active Layer

Using a polycrystalline sintered body having a composition of InGaZnO₄ as a target, a deposition layer of IGZO having a thickness of 50 nm was formed by an RF magnetron sputtering vacuum deposition method. The electric conductivity of the active layer was 5.7×10⁻³ Scm⁻¹. Patterning of the active layer was performed using a shadow mask during sputtering.

3) Gate Insulating Layer

A gate insulating layer was provided by performing RF magnetron sputtering vacuum deposition of SiO₂ to form a layer having a thickness of 200 nm. Patterning of the gate insulating layer was performed using a shadow mask during sputtering.

4) Gate Electrode

A gate electrode was provided by performing deposition of Mo to form a layer having a thickness of 100 nm. Patterning of the gate electrode was performed using a shadow mask during sputtering.

(Sealing)

Sealing of the organic EL display was performed using a glass substrate (#1737, manufactured by Corning) for a sealing plate and an ultraviolet-curable adhesive.

### 1-2. Preparation of Organic EL Display A for Comparison

In the organic EL display No. 1, the active layer was provided by performing deposition of pentacene, which is an organic semiconductor, to give a thickness of 50 nm. Thereby, organic EL display A for comparison was prepared.

### 1-3. Preparation of Organic EL Display No. 2

Preparation of organic EL display No. 2 of the invention was conducted in a similar manner to the process in the preparation of the organic EL display No. 1, except that the active layer was changed to have a bilayer configuration including an active layer and an electric resistance layer. The layer closer to the source electrode and the drain electrode is considered to be the electric resistance layer, and the layer closer to the gate insulating layer is considered to be the active layer.

Electric resistance layer: IGZO was deposited to give a thickness of 40 nm by an RF magnetron sputtering vacuum deposition method. The flow rates of argon (Ar) and oxygen (O₂) were controlled to give the electric conductivity of the electric resistance layer of 1.0×10⁻⁴ Scm⁻¹.

Active layer: IGZO was deposited to give a thickness of 10 nm. The flow rates of Ar and O₂ were controlled to give the electric conductivity of the active layer of 2.6×10⁻¹ Scm⁻¹.

### 1-4. Preparation of Organic EL Display No. 3

Preparation of organic EL display No. 3 of the invention was conducted in a similar manner to the process in the preparation of the organic EL display No. 2, except that the glass substrate and the sealing plate were each changed to a PEN substrate which has a SiON layer at a thickness of 40 nm as a barrier layer on both sides thereof.

### 2. Performance Evaluation

(Evaluation Items)

1) Method of Measuring Electric Conductivity

Samples for measurements of physical properties were prepared under the same condition as in the preparation of the active layer in the organic EL display described above, in which an active layer of 100 nm was provided directly on a glass substrate (#1737, manufactured by Corning). The samples for measurements of physical properties were analyzed by the conventional X-ray diffraction method. As a result, it was verified that the resultant IGZO layers were amorphous layers.

The electric conductivity of the sample for measurement of physical properties was determined by calculation based on measured sheet resistance and film thickness of the sample. Herein, when the sheet resistance is expressed by ρ (Ω/□), and the film thickness is expressed by d (cm), the electric conductivity σ (Scm⁻¹) is calculated by the equation σ=1/(ρ×d).

In the Example, in an environment of 20° C., the measurements were executed by a Loresta GP (manufactured by Mitsubishi Chemical Corp.) for the region of the samples for measurement of physical properties with sheet resistance less than 10⁷ (Ω/□), and the measurements were executed by a Hiresta UP (manufactured by Mitsubishi Chemical Corp.) for the region of sheet resistance of 10⁷ (Ω/□) or more. For measurements of film thickness of the samples for measurement of physical properties, a contact stylus-type surface profiler DekTak-6M (manufactured by ULVAC, Inc.) was used.

Further, measurements of characteristics of the prepared TFT were performed using a semiconductor parameter analyzer 4156C (manufactured by Agilent Technologies, Inc.). As a result, it was verified that the TFT using IGZO for the active layer, which is the configuration of the organic EL display of the invention, exhibited an N-type TFT, in which the current between the source electrode and drain electrode increases when a plus gate voltage is applied.

2) Element Performance

(1) Emission Brightness: the brightness, which was obtained when 20 volts was applied to the gate electrode of the driving TFT and 20 volts was applied to the anode of the organic EL element, was measured.

(2) Drive Durability: the gate voltage of the driving TFT and the voltage applied to the anode of the organic EL element were controlled so that the initial brightness became 100 cd/m², and the brightness obtained after conducting a 100 hour-driving test was measured.

### 3. Evaluation Results

The obtained results are shown in Table 1.

It is clear from the results shown in Table 1 that the organic EL display No. 1, in which an oxide TFT is formed on the organic EL element, exhibits higher brightness and higher durability than the conventional organic EL display A, in which an organic TFT is formed on the organic EL element. Further, it is also realized that the organic EL display No. 2 having two layers of an oxide semiconductor for the active layer exhibits still higher brightness and higher durability. And even on a film substrate, the organic EL display of the invention exhibits higher brightness and higher durability than the conventional organic EL display A.

TABLE 1

| | | Electric Resistance Layer | | | Active Layer | | | Element Performance | |
|---|---|---|---|---|---|---|---|---|---|
| | | | | Electric | | | Electric | Emission | Drive |
| | | | Thickness | Conductivity | | Thickness | Conductivity | Brightness | Durability |
| Display No. | Substrate | Material | (nm) | (Scm⁻¹) | Material | (nm) | (Scm⁻¹) | (cd/m²) | (cd/m²) |
| Inventive Organic EL | Glass | — | — | — | IGZO | 50 | 5.7 × 10⁻³ | 290 | 96 |
| Display No. 1 | | | | | | | | | |
| Compartive Organic EL | Glass | — | — | — | Pentacene | 50 | | 25 | 12 |
| Display A | | | | | | | | | |
| Inventive Organic EL | Glass | IGZO | 40 | 1.0 × 10⁻⁴ | IGZO | 10 | 2.6 × 10⁻¹ | 340 | 98 |
| Display No. 2 | | | | | | | | | |
| Inventive Organic EL | PEN | IGZO | 40 | 1.0 × 10⁻⁴ | IGZO | 10 | 2.6 × 10⁻¹ | 310 | 68 |
| Display No. 3 | | | | | | | | | |

### Example 2

### 2-1. Preparation of Organic EL Display No. 4

In the organic EL display No. 1 of Example 1, the method of forming the organic layer in the preparation of the organic EL element part was changed to the following method, and thereby organic EL display No. 4 was prepared.

<Formation of Organic Layer>

After cleaning, a hole injection layer, a hole transporting layer, a light-emitting layer, a hole blocking layer, an electron transport layer and an electron injection layer were disposed in this order.

The composition of each layer is as follows. Each layer was provided by resistance heating vacuum deposition.

Hole injection layer: a layer containing 4,4′,4″-tris(2-naphthylphenylamino)triphenylamine (which is referred to as 2-TNATA) and 2,3,5,6-tetrafluoro-7,7,8,8-tetracyanoquinodimethane (which is referred to as F4-TCNQ), wherein an amount of F4-TCNQ was 1% by weight with respect to 2-TNATA, at a thickness of 160 nm.

Hole transporting layer: N,N′-dinaphthyl-N,N′-diphenyl-[1,1′-biphenyl]-4,4′-diamine (which is referred to as α-NPD), at a thickness of 10 nm.

Light-emitting layer: a layer containing 1,3-bis(carbazol-9-yl)benzene (which is referred to as mCP) and platinum complex Pt-1, wherein an amount of Pt-1 was 13% by weight with respect to mCP, at a thickness of 60 inn.

Hole blocking layer: aluminium (III) bis(2-methyl-8-quinolinato)-4-phenylphenolate (which is referred to hereinafter as BAlq), at a thickness of 40 inn.

Electron transport layer: tris(8-hydroxyquinolinato) aluminum (which is referred to hereinafter as Alq3), at a thickness of 10 nm.

Electron injection layer: LiF, at a thickness of 1 nm.

Chemical structures of the compounds used in Examples are shown below.

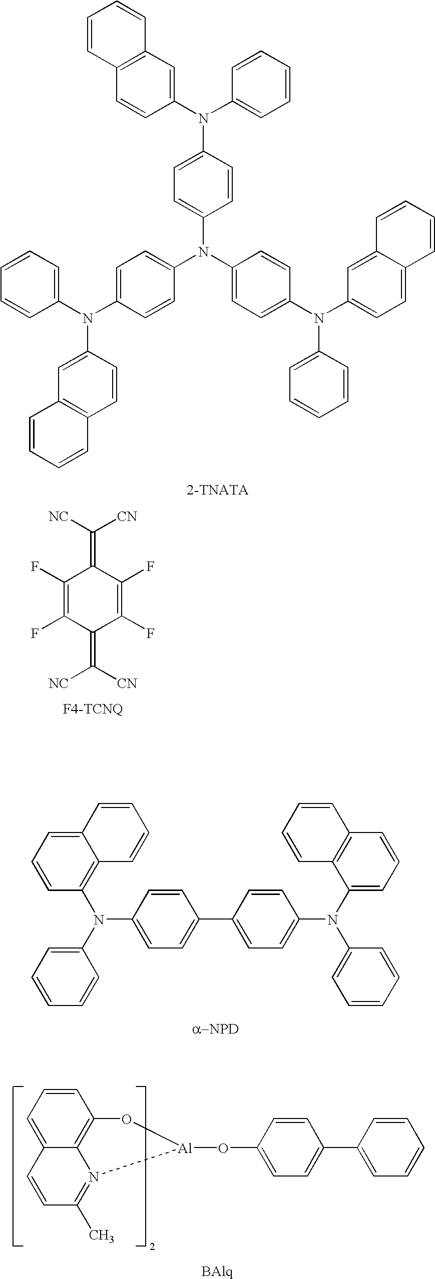

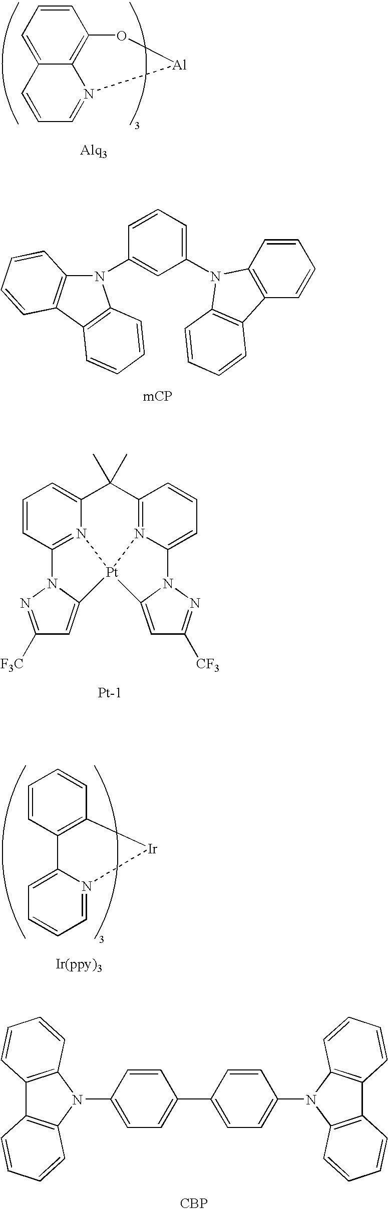

The brightness of the organic EL display No. 4 was measured, when 20 volts was applied to the gate electrode of the driving TFT and 20 volts was applied to the anode of the organic EL element. The organic EL display No. 4 exhibited an excellent blue-light emission, and brightness of 150 cd/m² was obtained.

### 2-2. Preparation of Organic EL Display No. 5

In the organic EL display No. 2 of Example 1, the formation of the organic layer in the preparation of the organic EL element portion was changed to the formation of the organic layer in the preparation of the organic EL display No. 4. Thereby, organic EL display No. 5 was prepared.

The brightness of the organic EL display No. 5 was measured, when 20 volts was applied to the gate electrode of the driving TFT and 20 volts was applied to the anode of the organic EL element. The organic EL display No. 5 exhibited an excellent blue-light emission, and brightness of 210 cd/m² was obtained.

What is claimed is:

1. An organic EL display comprising:
an organic EL element comprising at least a lower electrode, an organic layer comprising at least a light-emitting layer, and an upper electrode, in this order, on a substrate; and
a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor.

2. The organic EL display according to claim 1, wherein a protective insulating layer is disposed between the upper electrode and the thin film field effect transistor, and the upper electrode and at least one of the source electrode or the drain electrode are electrically connected through a contact hole formed in the protective insulating layer.

3. The organic EL display according to claim 1, wherein the lower electrode is a light transmitting electrode.

4. The organic EL display according to claim 3, wherein the upper electrode is a light reflective electrode.

5. The organic EL display according to claim 1, wherein the lower electrode is an anode, and the upper electrode is a cathode.

6. The organic EL display according to claim 5, wherein a polarity of the thin film field effect transistor is an N-type.

7. The organic EL display according to claim 1, wherein the oxide semiconductor of the active layer is an amorphous oxide semiconductor.

8. The organic EL display according to claim 1, wherein an electric resistance layer containing an oxide semiconductor is disposed between the active layer and at least one of the source electrode or the drain electrode.

9. The organic EL display according to claim 8, wherein the active layer is in contact with the gate insulating layer, and the electric resistance layer is in contact with at least one of the source electrode or the drain electrode.

10. The organic EL display according to claim 9, wherein the electric resistance layer is thicker than the active layer.

11. The organic EL display according to claim 8, wherein an electric conductivity changes continuously between the electric resistance layer and the active layer.

12. The organic EL display according to claim 8, wherein an oxygen concentration of the active layer is lower than an oxygen concentration of the electric resistance layer.

13. The organic EL display according to claim 8, wherein the oxide semiconductor of the active layer and the electric resistance layer is at least one material selected from the group consisting of In, Ga, and Zn, or a composite oxide thereof.

14. The organic EL display according to claim 13, wherein the oxide semiconductor contains In and Zn, and a composition ratio between Zn and In in the electric resistance layer (represented by a ratio of Zn to In, Zn/In) is larger than a composition ratio Zn/In in the active layer.

15. The organic EL display according to claim 8, wherein the active layer has an electric conductivity of 10⁻⁴ Scm⁻¹ or more, and less than 10² Scm⁻¹.

16. The organic EL display according to claim 15, wherein the active layer has an electric conductivity of 10⁻¹ Scm⁻¹ or more, and less than 10² Scm⁻¹.

17. The organic EL display according to claim 8, wherein a ratio of an electric conductivity of the active layer to an electric conductivity of the electric resistance layer (electric conductivity of active layer/electric conductivity of electric resistance layer) is from 10¹ to 10¹⁰.

18. The organic EL display according to claim 17, wherein the ratio of the electric conductivity of the active layer to the electric conductivity of the electric resistance layer (electric conductivity of active layer/electric conductivity of electric resistance layer) is from 10² to 10⁸.

19. The organic EL display according to claim 1, wherein the substrate is a flexible resin substrate.

20. A method of manufacturing an organic EL display comprising:
an organic EL element comprising on a substrate at least a lower electrode, an organic layer comprising at least a light-emitting layer, and an upper electrode, in this order; and
a thin film field effect transistor that is formed on the upper electrode and drives the organic EL element, the thin film field effect transistor comprising at least a gate electrode, a gate insulating layer, an active layer, a source electrode and a drain electrode, wherein the active layer contains an oxide semiconductor,
wherein the method comprises forming the organic EL element and forming the thin film field effect transistor successively on the substrate.
